(19) United States
(12) Patent Application Publication
(10) Pub. No.: US 2013/0137272 A1
(43) Pub. Date: May 30, 2013

(54) METHOD OF MANUFACTURING SEMICONDUCTOR DEVICE AND SUBSTRATE PROCESSING APPARATUS

(71) Applicant: HITACHI KOKUSAI ELECTRIC INC., Tokyo (JP)

(72) Inventors: Kiyohisa ISHIBASHI, Toyama-shi (JP); Atsushi MORIYA, Toyama-shi (JP)

(73) Assignee: HITACHI KOKUSAI ELECTRIC INC., Tokyo (JP)

(21) Appl. No.: 13/751,517

(22) Filed: Jan. 28, 2013

Related U.S. Application Data
(63) Continuation of application No. PCT/JP2011/066232, filed on Jul. 15, 2011.

(30) Foreign Application Priority Data
Aug. 26, 2010 (JP) 2010-189813

(51) Int. Cl. H01L 21/461; H01L 21/306; H01L 21/302

(52) U.S. Cl. CPC H01L 21/30604
USPC 438/706

(57) ABSTRACT

A method of manufacturing a semiconductor device, includes supplying a first etching gas and a second etching gas having a decomposition rate lower than that of the first etching gas from one end of a substrate accommodating region in a process chamber where a plurality of substrates are stacked while exhausting an inside of a process chamber from other end of the substrate accommodating region; and etching a first portion of the plurality of substrate at the one end of the substrate accommodating region using a portion of radicals generated from the first etching gas and second etching gas, and etching a second portion of the plurality of substrates at the other end of the substrate accommodating region using at least a portion of a remaining radicals of the radicals generated from the first etching gas and second etching gas.

### CROSS-REFERENCE TO RELATED PATENT APPLICATION

This U.S. non-provisional patent application claims priority under 35 U.S.C. §119 of Japanese Patent Application No. 2010-189813, filed on Aug. 26, 2010, in the Japanese Patent Office and International Patent Application No. PCT/JP2011/066232, filed on Jul. 15, 2011, in the WIPO, the entire contents of which are hereby incorporated by reference.

### BACKGROUND OF THE INVENTION

1. Field of the Invention

The present invention relates to a method of manufacturing a semiconductor device and a substrate processing apparatus.

2. Description of the Related Art

As a process included in a method of manufacturing a semiconductor device, an etching process of etching a substrate may be performed. In the etching process, the substrate is etched by loading the substrate into a process chamber included in a substrate processing apparatus, heating the inside of the process chamber to a desired temperature, and then supplying an etching gas, such as chlorine (Cl₂) gas or hydrogen chlorine (HCl) gas, into the process chamber after the temperature of the inside of the process chamber is stabilized (see Japanese Patent Application Laid-Open No. 2008-160123, Japanese Patent Application Laid-Open No. 2009-260015, Japanese Unexamined Patent Application Laid-Open No. 2009-505419, and Japanese Patent Application Laid-Open No. Hei 10-64889).

### SUMMARY OF THE INVENTION

However, when a plurality of pieces of stacked substrates are etched, the etching uniformity in planes of the substrates or between other substrates may be lowered. To address this problem, it is an object of the present invention to provide a method of manufacturing a semiconductor device capable of uniformizing the etching uniformity in the planes of the substrates or between other substrates and a substrate processing apparatus.

According to one aspect of the present invention, there is provided a method of manufacturing a semiconductor device, including supplying a first etching gas and a second etching gas having a decomposition rate lower than that of the first etching gas from one end of a substrate accommodating region in a process chamber where a plurality of substrates are stacked while exhausting an inside of a process chamber from other end of the substrate accommodating region; and etching a first portion of the plurality of substrate at the one end of the substrate accommodating region using a portion of radicals generated from the first etching gas and second etching gas, and etching a second portion of the plurality of substrates at the other end of the substrate accommodating region using at least a portion of a remaining radicals of the radicals generated from the first etching gas and second etching gas.

According to another aspect of the present invention, there is provided a method of manufacturing a semiconductor device, including supplying a chlorine gas and a hydrogen chloride gas from one end of a substrate accommodating region in a process chamber where a plurality of substrates are stacked while exhausting an inside of the process chamber from other end of the substrate accommodating region; and etching the plurality of substrate by further supplying at least one of the chlorine gas and the hydrogen chloride gas from a location between the one end and the other end of the substrate accommodating region.

According to still another aspect of the present invention, there is provided a substrate processing apparatus including a process chamber having a substrate accommodating region where a plurality of substrates are stacked; a gas supply unit configured to supply a first etching gas and a second etching gas having a decomposition rate lower than that of the first etching gas from one end of the substrate accommodating region; and an exhaust unit configured to exhaust an inside of the process chamber from other end of the substrate accommodating region, wherein a first portion of the plurality of substrate at the one end of the substrate accommodating region is etched using a portion of radicals generated from the first etching gas and second etching gas, and etching a second portion of the plurality of substrates at the other end of the substrate accommodating region using at least a portion of a remaining radicals of the radicals generated from the first etching gas and second etching gas.

According to yet another aspect of the present invention, there is provided a substrate processing apparatus including a process chamber having a substrate accommodating region where a plurality of substrates are stacked; a gas supply unit configured to supply a chlorine gas and a hydrogen chloride gas from one end of the substrate accommodating region; an exhaust unit configured to exhaust an inside of the process chamber from other end of the substrate accommodating region; and a control unit configured to control the gas supply unit and the exhaust unit, wherein the control unit controls the gas supply unit and the exhaust unit so as to etch a first portion of the plurality of substrate at the one end of the substrate accommodating region using a portion of chlorine radicals generated from the chlorine gas and the hydrogen chloride gas and a second portion of the plurality of substrates at the other end of the substrate accommodating region using at least a portion of a remaining radicals of the chlorine radicals while exhausting the inside of the process chamber from other end of the substrate accommodating region.

According to yet another aspect of the present invention, there is provided a substrate processing apparatus including a process chamber having a substrate accommodating region where a plurality of substrates are stacked; a first gas supply unit configured to supply a chlorine gas and a hydrogen chloride gas from one end of the substrate accommodating region; a second gas supply unit configured to supply at least one of the chlorine gas and the hydrogen chloride gas from a location between the one end and other end of the substrate accommodating region opposite to the one end; an exhaust unit configured to exhaust an inside of the process chamber from the other end of the substrate accommodating region; and a control unit configured to control the first gas supply unit, the second gas supply unit and the exhaust unit, wherein the control unit controls the first gas supply unit, the second gas supply unit and the exhaust unit so as to supply the chlorine gas and the hydrogen chloride gas from the one end by the first gas supply unit while exhausting the inside of the process chamber from the other end and etch the plurality of substrate by further supplying at least one of the chlorine gas and the hydrogen chloride gas from the location by the second gas supply unit.

### BRIEF DESCRIPTION OF THE DRAWINGS

FIG. 1 is a schematic configuration diagram of a substrate processing apparatus according to a first embodiment of the present invention.

FIG. 2 is a schematic configuration diagram of a process chamber according to the first embodiment of the present invention.

FIGS. 3A and 3B are schematic configuration diagrams of a gas supply system according to the first embodiment of the present invention.

FIG. 4 is a flowchart illustrating a substrate processing process according to the first embodiment of the present invention.

FIGS. 5A and 5B are diagrams comparing contribution of an etching gas used during an etching process in a conventional method (FIG. 5A) with that in the first embodiment of the present invention (FIG. 5B).

FIG. 6 is a table illustrating a result of measuring etching uniformity and an etching rate.

FIG. 7 is a schematic configuration diagram of a process chamber according to a second embodiment of the present invention.

FIGS. 8A and 8B are schematic configuration diagrams of a gas supply system according to the second embodiment of the present invention.

FIG. 9 is a schematic configuration diagram of a process chamber according to a third embodiment of the present invention.

FIGS. 10A and 10B are schematic configuration diagrams of a gas supply system according to the third embodiment of the present invention.

FIG. 11 is a schematic configuration diagram of a process chamber according to a combination of the second and third embodiments of the present invention.

FIGS. 12A and 12B are schematic configuration diagrams of a gas supply system according to a combination of the second and third embodiments of the present invention.

FIG. 13 is a schematic configuration diagram of a process chamber according to a fourth embodiment of the present invention.

FIG. 14 is a diagram illustrating a process of etching a wafer on which an insulating film is formed, according to a fifth embodiment of the present invention.

FIG. 15 is a flowchart illustrating a substrate processing process according to a sixth embodiment of the present invention.

FIG. 16 is a diagram illustrating the substrate processing process according to the sixth embodiment of the present invention.

### DETAILED DESCRIPTION OF THE PREFERRED EMBODIMENTS

### First Embodiment of the Present Invention

(1) Construction of Substrate Processing Apparatus

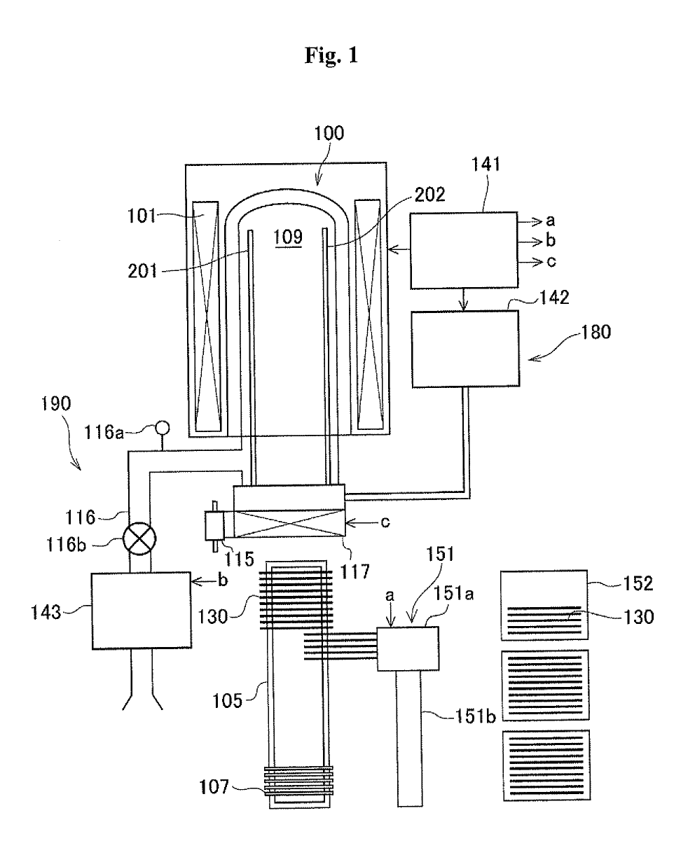

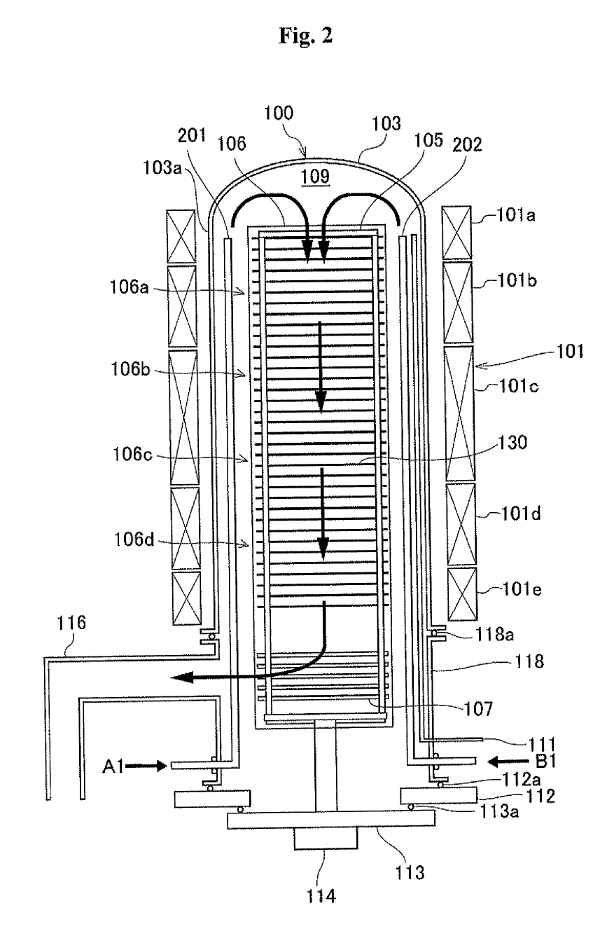

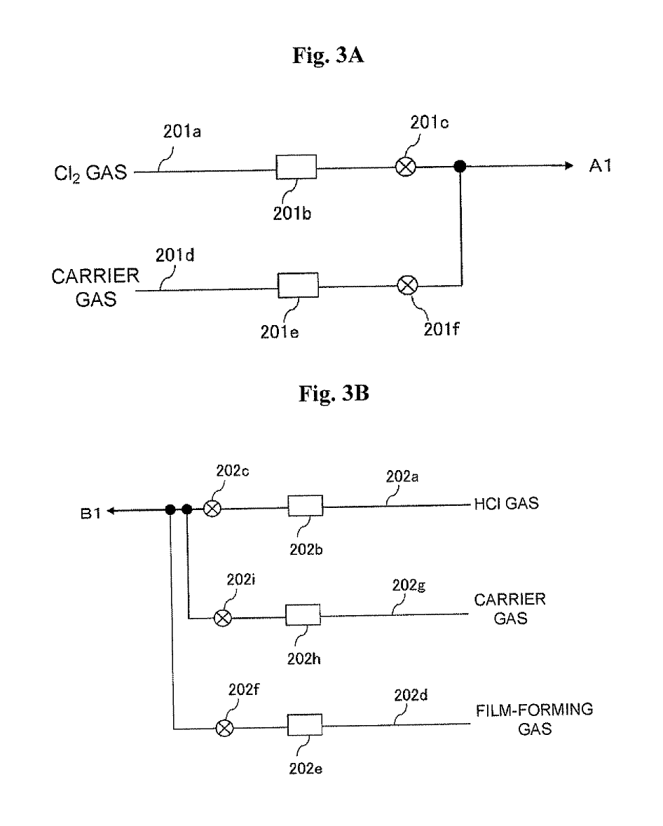

FIG. 1 is a schematic configuration diagram of a substrate processing apparatus according to a first embodiment of the present invention. FIG. 2 is a schematic configuration diagram of a process chamber according to the first embodiment of the present invention. FIGS. 3A and 3B are schematic configuration diagrams of a gas supply system according to the first embodiment of the present invention.

Referring to FIG. 1, a process furnace 100 includes a heater 101 as a heating device (heating member). Referring to FIG. 2, the heater 101 is sequentially divided into an upper heater 101a, a central upper heater 101b, a central heater 101c, a central lower heater 101d and a lower heater 101e in a direction from a top of the process furnace 100 to a bottom thereof. In the heater 101, each of the upper heater 101a, the central upper heater 101b, the central heater 101c, the central lower heater 101d and the lower heater 101e has a cylindrical shape, and is vertically installed with support from a heater base (not shown) as a supporting plate. As will be described below, the heater 101 acts as an activating mechanism (activating member) that activates (radicalizes) an etching gas by heat.

As illustrated in FIG. 2, in the heater 101, a reaction tube 103 forming a reaction container (process container) concentrically with the heater 101 is provided. The reaction tube 103 is formed of a heat-resistive material, e.g., quartz (SiO₂) or silicon carbide (SiC), and has a cylindrical shape, the upper end of which is closed and the lower end of which is open. A process chamber 109 is formed in a hollow portion of the reaction tube 103. In the process chamber 109, a substrate accommodating region 106 is provided to accommodate a plurality of stacked wafers 130 (substrates). Specifically, in the substrate accommodating region 106, the wafers 130 are received in a state in which the wafers 130 are arranged in a vertical multi-layer structure in a horizontal posture by a boat 105 which will be described below.

An inlet flange 118 is installed below the reaction tube 103. The inlet flange 118 is configured to vertically abut a lower end of the reaction tube 103. The inlet flange 118 is formed of metal, e.g., stainless steel, and has a cylindrical shape. An O-ring 118a that abuts the lower end of the reaction tube 103 is installed as a seal member on an upper surface of the inlet flange 118.

In the reaction tube 103, a first nozzle 201 and a second nozzle 202 are installed. The first nozzle 201 and the second nozzle 202 are installed to be bent toward the reaction tube 103 in the inlet flange 118 while passing through sidewalls of the inlet flange 118, and to rise upward within a space having a circular arc shape between sidewalls 103a of the reaction tube 103 and the wafers 130, in a stacking direction of the wafers 130. The first nozzle 201 and the second nozzle 202 are configured in such a manner that front ends (downstream ends) thereof may be disposed near an upper end of the boat 105, and are configured to supply a gas via the upper end of the boat 115 (one end of the substrate accommodating region 106). In other words, the first nozzle 201 and the second nozzle 202 are configured to supply a gas to a region between the upper end of the boat 105 and an upper end of the reaction tube 103. As illustrated in FIGS. 3A and 3B, an upstream end of the first nozzle 201 is connected to a downstream end of a first gas supply pipe 201a, and an upstream end of the second nozzle 202 is connected to a downstream end of a second gas supply pipe 202a. As described above, in the reaction tube 103, two nozzles, i.e., the first nozzle 201 and the second nozzle 202, are installed to supply a plurality of types of gases into the reaction tube 103.

As illustrated in FIG. 3A, in the first gas supply pipe 201a, a mass flow controller (MFC) 210b which is a flow rate controller (flow rate control unit) and a valve 201c which is a switch valve are sequentially installed in an upstream direction. Also, a downstream end of a first carrier gas supply pipe 201d is connected to the first gas supply pipe 201a at a downstream side of the valve 201c. In the first carrier gas supply pipe 201d, an MFC 201e which is a flow rate controller (flow rate control unit) and a valve 201f which is a switch valve are sequentially installed in the upstream direction.

Referring to FIG. 3B, in the second gas supply pipe 202a, an MFC 202b which is a flow rate controller (flow rate control unit) and a valve 202c which is a switch valve are sequentially installed in an upstream direction. A downstream end of a second carrier gas supply pipe 202d is connected to the second gas supply pipe 202a at a downstream side of the valve 202c. In the second carrier gas supply pipe 202d, an MFC 202e which is a flow rate controller (flow rate control unit) and a valve 202f which is a switch valve are sequentially installed in the upstream direction. Also, a downstream end of a first film-forming gas supply pipe 202g is connected to the second gas supply pipe 202a at a downstream side of the valve 202c. In the first film-forming gas supply pipe 202g, an MFC 202h which is a flow rate controller (flow rate control unit) and a valve 202i which is a switch valve are sequentially installed in an upstream direction.

The gas supply unit 180 according to the current embodiment is mainly configured by the first gas supply pipe 201a, the MFC 201b, the valve 201e, the first carrier gas supply pipe 201d, the MFC 201e, the valve 201f, the first nozzle 201, the second gas supply pipe 202a, the MFC 202b, the valve 202c, the second carrier gas supply pipe 202d, the MFC 202e, the valve 202f, the first film-forming gas supply pipe 202g, the MFC 202h, the valve 202i and the second nozzle 202.

Through the first gas supply pipe 201a, a first etching gas, e.g., chlorine (Cl₂) gas, is supplied into the process chamber 109 via the MFC 201b, the valve 201c and the first nozzle 201. Through the first carrier gas supply pipe 201d, a carrier gas, e.g., hydrogen (H₂) gas or nitrogen (N₂) gas, is supplied into the process chamber 109 via the MFC 201e, the valve 201f and the first nozzle 201.

Through the second gas supply pipe 202a, a second etching gas having a lower decomposition rate than that of the first etching gas, e.g., hydrogen chloride (HCl) gas, is supplied into the process chamber 109 via the MFC 202b, the valve 202e and the second nozzle 202. Through the second carrier gas supply pipe 202d, the carrier gas, e.g., the hydrogen (H₂) gas or the nitrogen (N₂) gas, is supplied into the process chamber 109 via the MFC 202e, the valve 202f and the second nozzle 202. Through the first film-forming gas supply pipe 202g, for example, a silicon source gas, i.e., a film-forming gas containing silicon (Si) (hereinafter referred to as ‘silicon-containing gas’), is supplied into the process chamber 109 via the MFC 202h, the valve 202i and the second nozzle 202. The silicon-containing gas may be, for example, monosilane (SiH₄), disilane (Si₂H₆), dichlorosilane (SiH₂Cl₂), or the like.

As illustrated in FIG. 2, in the inlet flange 118, a gas exhaust pipe 116 is installed to exhaust an atmosphere in the process chamber 109. As illustrated in FIG. 1, in the gas exhaust pipe 116, a pressure sensor 116a which is a pressure detector for detecting pressure in the process chamber 109, an auto pressure controller (APC) valve 116b which is a pressure adjustment machine, and a vacuum pump 143 which is a vacuum exhaust device are installed from an upstream side so as to perform vacuum exhaust so that the pressure into the process chamber 109 may be equal to a predetermined pressure (degree of vacuum). The APC valve 116b is a switch valve capable of vacuum-exhausting the inside of the process chamber 109 and suspending the vacuum-exhausting of the inside of the process chamber 109 by being opened/closed, and performing pressure control by adjusting the degree of opening thereof. An exhaust unit 190 according to the current embodiment is mainly configured by the gas exhaust pipe 116, the APC valve 116b.

As illustrated in FIG. 2, a base 112 is installed below the inlet flange 118 as a supporting member to support the reaction tube 103. The base 112 is configured to vertically abut a lower end of the inlet flange 118. The base 112 is formed of a metal, e.g., stainless steel, and has a circular shape. An O-ring 112a is installed as a seal member that abuts the lower end of the inlet flange 118 on an upper surface of the base 112.

A seal cap 113 which functions as a furnace port lid configured to air-tightly close a lower end opening of the inlet flange 118 is installed below the base 112. The seal cap 113 is configured to vertically abut a lower end of the base 112. The seal cap 113 is formed of a metal, e.g., stainless steel, and has a disc shape. An O-ring 113a is installed as a seal member that abuts the lower end of the base 112 on an upper surface of the seal cap 113. At a side of the seal cap 113 opposite to the process chamber 109, a rotating mechanism 114 that rotates the boat 105 which will be described below is installed. A rotation shaft of the rotating mechanism 114 is connected to the boat 105 while passing through the seal cap 113, and is configured to rotate the wafers 130 by rotating the boat 105. The seal cap 113 is configured to be vertically moved upward/downward by a boat elevator 115 which is a lift mechanism vertically installed outside the reaction tube 103. By vertically moving the seal cap 113 upward/downward, the boat 105 may be loaded into or unloaded from the process chamber 109.

The boat 105 which is a substrate supporter is formed of a heat-resistive material, e.g., quartz or silicon carbide, and is configured to hold the plurality of wafers 130 in the form of a multi-layer structure by arranging the plurality of wafers 130 horizontally and concentrically. Also, a plurality of insulating plates 107 formed of a heat-resistive material, e.g., quartz or silicon carbide, are formed in a multi-layer structure below the boat 105, thereby preventing heat generated from the heater 101 from being delivered to the seal cap 113. Instead of the insulating plates 107, an insulating member may be installed below the boat 105 while being supported by a support member installed near a lower end of the boat 105.

In the reaction tube 103, a temperature sensor 111 is installed as a temperature detector. The temperature sensor 111 has an ‘L’ shape, similar to the first nozzle 201 and the second nozzle 202, and is installed to rise upward in the space having the circular arc shape between sidewalls 103a of the reaction tube 103 and the wafers 130 along the sidewalls 103a of the reaction tube 103, in the stacking direction of the wafers 130. In the current embodiment, the amount of current flowing through the heater 101 is adjusted based on temperature information detected by the temperature sensor 111, thereby allowing a temperature in the process chamber 109 to have a desired temperature distribution.

As illustrated in FIG. 1, a wafer transfer mechanism 151 is installed below the process furnace 100. The wafer transfer mechanism 151 includes a wafer transfer machine 151a (substrate transfer machine) that may horizontally rotate the wafers 130 or allow the wafers 130 to move linearly, and a wafer transfer machine elevator 151b (substrate transfer machine elevator) that moves the wafer transfer machine 151a upward/downward. As illustrated in FIG. 1, the wafer transfer machine elevator 151b is installed between the boat 105 moved downward in the process chamber 109 and a wafer cassette 152 configured to receive the wafers 130 before or after substrate processing is performed. The wafer transfer mechanism 151 is configured to transfer the wafers 130 between the boat 105 and the wafer cassette 152 by continuously operating the wafer transfer machine 151a and the wafer transfer machine elevator 151b.

A controller 141 which is a control unit is connected to the gas supply unit 180 and the exhaust unit 190 described above, and is configured to control the gas supply unit 180 and the exhaust unit 190 to perform substrate processing. Specifically, the controller 141 is connected to the MFCs 201b, 201e, 202b, 202e and 202h, the valves 201c, 201f, 202c, 202f and 202i, the pressure sensor 116c, the APC valve 116b, the vacuum pump 143, the heater 101 (including the heaters 101a, 101b, 101c, 101d and 101e), the temperature sensor 111, the rotating mechanism 114, the boat elevator 115, and so on. The controller 141 controls the flow rates of various gases (the first and second etching gases, the carrier gas, the film-forming gas, etc.) using the MFCs 201b, 201e, 202b, 202e and 202h; opening/closing of the valves 201c, 201f, 202c, 202f and 202i; opening/closing of the APC valve 116b; pressure based on the pressure sensor 116a; a temperature of the heater 101 (including the heaters 101a, 101b, 101c, 101d and 101e) based on the temperature sensor 111, operating/suspending of the vacuum pump 143, the speed of rotating the rotating mechanism 114, moving of the boat elevator 115 upward/downward, etc.

(2) Substrate Processing Process

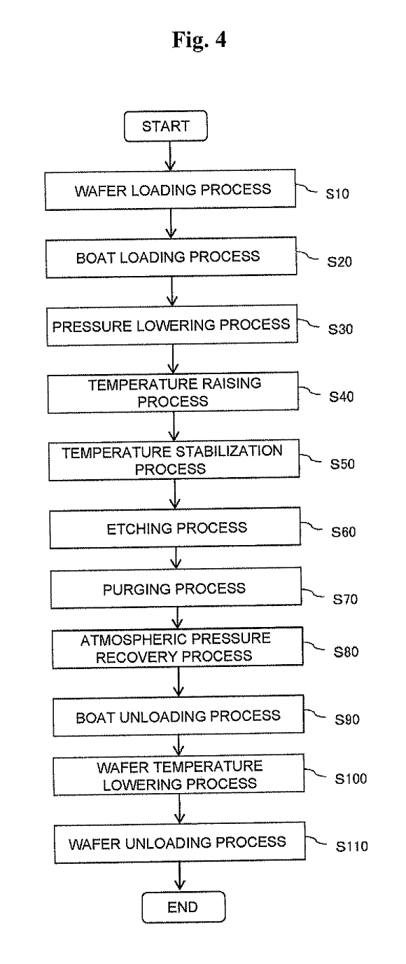

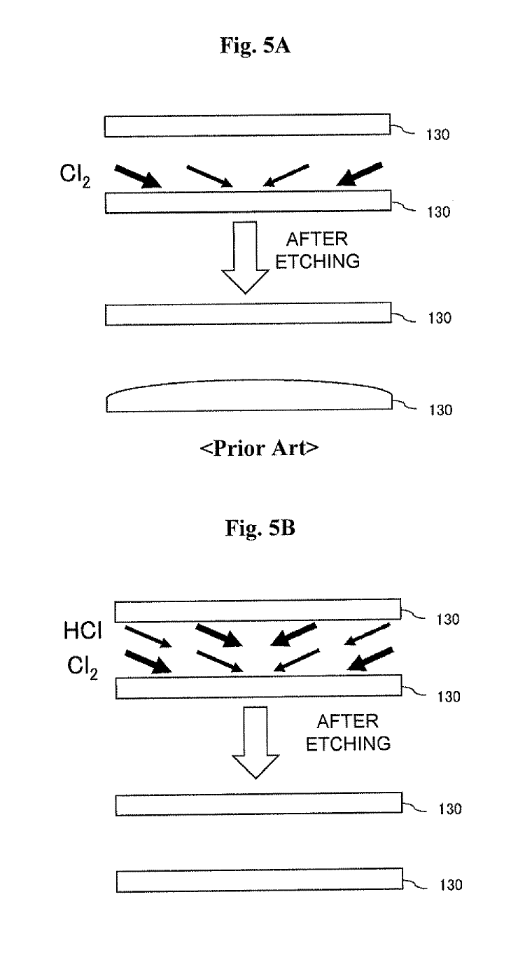

Next, a substrate processing process which is a process included in a method of manufacturing a semiconductor device, performed by a substrate processing apparatus, according to the current embodiment will be described. FIG. 4 is a flowchart illustrating a substrate processing process according to the first embodiment of the present invention. FIGS. 5A and 5B are diagrams comparing contribution of an etching gas used during an etching process in a conventional method (FIG. 5A) with that in the first embodiment of the present invention (FIG. 5B).

As illustrated in FIG. 4, the substrate processing process according to the current embodiment includes a wafer loading process (S10), a boat loading process (S20), a pressure lowering process (S30), a temperature raising process (S40), a temperature stabilization process (S50), an etching process (S60), a purging process (S70), an atmospheric pressure recovery process (S80), a boat unloading process (S90), a wafer temperature lowering process (S100) and a wafer unloading process (S110). The substrate processing process according to the current embodiment will now be described in detail.

[Wafer Loading Process (S10)]

First, the wafer transfer machine 151a is moved to the wafer cassette 152 of FIG. 1 using the wafer transfer mechanism 151 of FIG. 1. By continuously operating the wafer transfer machine elevator 151b and the wafer transfer machine 151a together, the wafer transfer machine 151a unloads the wafers 130 from the wafer cassette 152 and then charges the wafers 130 in the boat 105. The wafers 130 in the boat 105 are arranged horizontally and concentrically and are supported in a multi-layer structure.

[Boat Loading Process (S20)]

Desired sheets of the wafers 130 are placed in the boat 105, and the boat 105 is lifted by the boat elevator 115 of FIG. 1 and is then received in the substrate accommodating region 106 in the process chamber 109. Then, the lower end of the inlet flange 118 is air-tightly closed with the seal cap 113 via the O-ring 113a. In this case, since the valves 201c, 201f, 202c, 202f and 202i of the gas supply unit 180 and the APC valve 116b of the exhaust unit 190 are closed, the lower end of the inlet flange 118 is air-tightly closed with the seal cap 113, thereby sealing the process chamber 109. When the boat 105 is received in the process chamber 109, the temperature of the process chamber 109 is set to 400° C. or less.

[Pressure Lowering Process (S30)]

Next, the APC valve 116b of the exhaust unit 190 is opened, and the inside of the sealed process chamber 109 is exhausted to have a desired pressure (degree of vacuum). In this case, the pressure in the process chamber 109 is measured using the pressure sensor 116a, and an operation of the APC valve 116b is feedback-controlled based on the measured pressure.

[Temperature Raising Process (S40), Temperature Stabilization Process (S50)]

Also, the inside of the process chamber 109 is heated using the heater 101 (including the heaters 101a, 101b, 101c, 101d and 101e) while exhausting the inside of the process chamber 109 [temperature raising process (S40)]. In this case, an inner temperature of the process chamber 109 is measured using the temperature sensor 111, and the amount of current to be supplied to (or the amount of heat to be generated by) the heater 101 (including the heaters 101a, 101b, 101c, 101d and 101e) is feedback-controlled based on the measured temperature. In this case, an inner temperature of the process chamber 109 is set to be 400° C. or more or less than 700° C. by appropriately controlling the amount of current to be supplied to the heater 101. Then, rotation of the boat 105 starts. When the inside of the process chamber 109 is heated to a desired temperature, the boat 105 stands by until the temperature of the process chamber 109 is stabilized [temperature stabilization process (S50)].

[Etching Process (S60)]

Next, the desired sheets of the wafers 130 are etched. Chlorine (Cl₂) gas is supplied into the first gas supply pipe 201a by opening the valve 201c of the first gas supply pipe 201a. The flow rate of the chlorine (Cl₂) gas flowing through the first gas supply pipe 201a is adjusted by the MFC 201b. The chlorine (Cl₂) gas, the flow rate of which is adjusted is exhausted via the gas exhaust pipe 116 while being heated by the heater 101 to be supplied to a region between the upper end of the boat 105 and an upper end of the reaction tube 103 via a front end of the first nozzle 201. At the same time, hydrogen (H₂) gas is supplied into the first carrier gas supply pipe 201d by opening the valve 201f of the first carrier gas supply pipe 201d. The flow rate of the hydrogen (H₂) gas flowing through the first carrier gas supply pipe 201d is adjusted by the MFC 201e. The hydrogen (H₂) gas, the flow rate of which is adjusted, is heated by the heater 101 to be supplied to the region between the upper end of the boat 105 and the upper end of the reaction tube 103 via the front end of the first nozzle 201, together with the chlorine (Cl₂) gas. The hydrogen (H₂) gas is exhausted by the gas exhaust pipe 116 while promoting diffusion of the chlorine (Cl₂) gas in the process chamber 109.

Also, hydrogen chloride (HCl) gas is supplied into the second gas supply pipe 202a by opening the valve 202c of the second gas supply pipe 202a. The flow rate of the hydrogen chloride (HCl) gas flowing through the second gas supply pipe 202a is adjusted by the MFC 202b. The hydrogen chloride (HCl) gas, the flow rate of which is adjusted, is exhausted via the gas exhaust pipe 116 while being heated by the heater 101 to be supplied into the region between the upper end of the boat 105 and the upper end of the reaction tube 103 via a front end of the second nozzle 202. At the same time, hydrogen (H₂) gas is supplied into the second carrier gas supply pipe 202d by opening the valve 202f of the second carrier gas supply pipe 202d. The flow rate of the hydrogen (H₂) gas flowing through the second carrier gas supply pipe 202d is adjusted by the MFC 202e. The hydrogen (H₂) gas, the flow rate of which is adjusted, is heated by the heater 101 to be supplied into the region between the upper end of the boat 105 and the upper end of the reaction tube 103, together with the hydrogen chloride (HCl) gas. The hydrogen (H₂) gas is exhausted via the gas exhaust pipe 116 while expediting diffusion of the hydrogen chloride (HCl) gas in the process chamber 109.

Thus, during the etching process (S60), two types of etching gases having different speeds of decomposition, e.g., the chlorine (Cl₂) gas and the hydrogen chloride (HCl) gas, are simultaneously supplied into the process chamber 109.

In this case, the APC valve 116b is appropriately adjusted to set the pressure in the process chamber 109 to fall within, for example, a range of 10 Pa to 100 Pa. The flow rate of the chlorine (Cl₂) gas is set to fall within, for example, a range of 0 to 100 sccm by appropriately controlling the valve 201c of the first gas supply pipe 201a. The flow rate of the hydrogen chloride (HCl) gas is set to fall within, for example, a range of 0 to 500 sccm by appropriately controlling the valve 202c of the second gas supply pipe 202a. The flow rate of a carrier gas, such as hydrogen (H₂) gas or nitrogen (N₂) gas, is set to fall within, for example, a range of 0 to 20,000 sccm by appropriately controlling the valve 201f of the first carrier gas supply pipe 201d and the valve 202f of the second carrier gas supply pipe 202d.

Although each of the flow rates of the chlorine (Cl₂) gas and the hydrogen chloride (HCl) gas is described as having a minimum value of 0, ‘0’ here should be understood as at least an extremely small amount of an etching gas being supplied. In other words, during the etching process (S60), the desired sheets of the wafer 130 are etched by two types of etching gases rather than only one type of etching gas. That is, etching by a single etching gas is not performed.

The reason for which two types of etching gases having different speeds of decomposition should be simultaneously supplied into the process chamber 109 during the etching process (S60) will now be described.

When a plurality of stacked wafers 130 (substrates) are received in the process chamber 109, a gap region between the wafers 130 are limited by the distance between every two adjacent wafers 130. Thus, an etching gas travels toward central parts of the wafers 130 from peripheral portions of the wafers 130.

In this case, if the etching gas has a high decomposition rate, e.g., chlorine (Cl₂) gas, then the etching gas supplied into the process chamber 109 is immediately decomposed. Then, as illustrated in FIG. 5A, most of the etching gas may be consumed at the peripheral portions of the wafers 130 and a sufficient amount of the etching gas is thus not supplied to the central parts of the wafers 130. In this case, since the rate at which the peripheral portions are etched is higher than that at which the central parts are etched, the surfaces of the wafers 130 may not be evenly etched. That is, the amounts to which the peripheral portions of the wafers 130 are etched are greater than those of the central parts of the wafers 130, and thus a main surface of the wafer 130 is likely to have a convex shape, thereby lowering etching uniformity in the planes of the wafers 130.

Also, in this case, most of the etching gas is consumed at an upstream side of the gas flow, and an insufficient amount of the etching gas is thus supplied at a downstream side thereof. Thus, the speed of etching at the downstream side is low, the amounts to which the wafers 130 are etched at the upstream side and the amounts to which the wafers 130 are etched at the downstream side become different.

On the other hand, if the etching gas has a low decomposition rate, e.g., hydrogen chloride (HCl) gas, the etching gas supplied into the process chamber 109 is not directly decomposed. Thus, most of the etching gas heading toward the central parts of the wafers 130 from the peripheral portions thereof is not consumed at the peripheral portions but travels to the central parts. Then, the etching gas is decomposed at the central parts and is mainly consumed at the central parts. Thus, the wafers 130 cannot be evenly etched since the speed at which the central parts are etched is higher than that at which the peripheral portions are etched. In other words, the amounts to which the central parts are etched are greater than those to which the peripheral portions are etched, and the main surface of each of the wafers 130 is likely to have a concave shape. Thus, the etching uniformity in the planes of the wafers 130 is lowered. Furthermore, since the amount of decomposing the etching gas at the downstream side of the gas flow is greater than that of decomposing the etching gas at the upstream side thereof, most of the etching gas may be consumed at the peripheral portions and a sufficient amount of the etching gas may not be supplied at the central parts. Thus, the main surface of each of the wafers 130 is likely to have a convex shape. In this case, the etching uniformity in the planes in the wafers 130 is also lowered.

Also, when the etching gas is decomposed and consumed, an amount of the etching gas may become insufficient before the etching gas arrives at the downstream side. In this case, the speed of etching at the downstream side is low, and the amounts of etching the wafers 130 at the upstream side and those of etching the wafers 130 at the downstream side may be different.

Even if the plurality of the wafer 130 are stacked, the wafers 130 may be evenly etched in some degree by suppressing the flow rate of the etching gas. However, since the speed of etching is low in this case, this method may not be considered effective. Also, when the speed of etching is low, a time required to perform the etching increases, thereby lowering the yield.

For this reason, in the current embodiment, two types of etching gases having different speeds of decomposition are simultaneously supplied into the process chamber 109, so that the peripheral portions and central parts of the wafers 130 may be mainly etched by an etching gas having a high decomposition rate, e.g., chlorine (Cl₂) gas, and an etching gas having a low decomposition rate, e.g., hydrogen chloride (HCl) gas, respectively, thereby improving etching uniformity in the planes of the wafers 130. Also, etching is performed at the upstream side of the gas flow using the chlorine (Cl₂) gas, and is performed at a mid-stream side and downstream side of the gas flow by supplying the hydrogen chloride (HCl) gas to supplement for the deficiency of the chlorine (Cl₂) gas, thereby improving etching uniformity between the wafers 130.

The etching process (S60) will now be described in more detail. The chlorine (Cl₂) gas supplied into the process chamber 109 is already heated by the heater 101. Thus, the chlorine (Cl₂) gas having a high decomposition rate is thermally decomposed as soon as it is supplied into the process chamber 109, thereby generating chlorine radicals having high reactivity. Also, a portion of the chlorine (Cl₂) gas may be thermally decomposed in the first nozzle 201, thereby generating chlorine radicals. The chlorine radicals flow in a region between the boat 105 and the sidewalls 103a of the reaction tube 103, toward the lower end of the boat 105 (other end of the substrate accommodating region). During this process, a portion of chlorine radicals arrive at the gap regions between the wafers 130 at the upper end of the boat 105. At least a portion of the remaining chlorine radicals arrive at the gap regions between the other adjacent wafers 130, i.e., the adjacent wafers 130 at the lower end of the boat 105. As described above, according to the flow of the chlorine (Cl₂) gas, at least a portion of the remaining chlorine radicals arrive at the gap regions between the other adjacent wafers 130 at the lower end of the boat 105 (a lower end of the substrate accommodating region 106.

Most of the chlorine radicals arriving at the gap regions between the wafers 130 are consumed at the peripheral portions of the wafers 130, thus mainly etching the peripheral portions (see FIG. 5A). The remaining chlorine radicals that are not consumed at the peripheral portions pass through the peripheral portions and then arrive at the central parts of the wafers 130. A compound generated when the wafers 130 are etched flows to the lower end of the boat 105 and is then exhausted via the gas exhaust pipe 116, according to the flow of the gas.

The hydrogen chloride (HCl) gas supplied into the process chamber 109 is already heated by the heater 101. However, only a portion of the hydrogen chloride (HCl) gas having a low decomposition rate is decomposed to generate chlorine radicals, while the remaining majority of the hydrogen chloride (HCl) gas is not thermally decomposed and flows in the process chamber 109 for a long time even after it is supplied into the process chamber 109. The hydrogen chloride (HCl) gas flows in the region between the boat 105 and the sidewalls 113a of the reaction tube 103 toward the lower end of the boat 105. During this process, only a portion of the hydrogen chloride (HCl) gas arrives at the gap regions between the wafers 130 at the upper end of the boat 105. At least a portion of the remaining hydrogen chloride (HCl) gas arrives at the gap regions between the adjacent wafers 130, i.e., the adjacent wafers 130 at the lower end of the wafer 130. As described above, according to the flow of the hydrogen chloride (HCl) gas, at least a portion of the remaining hydrogen chloride (HCl) gas arrives at the gap regions between the remaining wafers 130 at the lower end of the boat 105 (the lower end of the substrate accommodating region 106). The hydrogen chloride (HCl) gas arriving at the gap regions between the wafers 130 flows to the central parts of the wafers 130 via the peripheral portions thereof.

Also, thermal decomposition of the hydrogen chloride (HCl) gas is promoted at the central parts of the wafers 130 by the remaining chlorine radicals generated from the chlorine (Cl₂) gas, thereby generating chlorine radicals from the hydrogen chloride (HCl) gas. Also, a portion of the heated hydrogen chloride (HCl) gas is thermally decomposed to generate chlorine radicals. Most of the chlorine radicals generated at the central parts of the wafers 130 are consumed at the central parts of the wafers 130 to mainly etch the central parts, and the remaining chlorine radicals are consumed to etch the peripheral portions of the wafers 130 (see FIG. 5B). A reaction material generated when the chlorine radicals and the wafers 130 react with one another when etching is performed (hereinafter referred to as an ‘etching reaction material’) flows to the lower end of the boat 105 and is then exhausted via the gas exhaust pipe 116, according to the flow of the gas.

As described above, in the etching process (S60) according to the current embodiment, the wafers 130 are etched by simultaneously supplying chlorine (Cl₂) gas having a high decomposition rate and hydrogen chloride (HCl) gas having a lower speed of deposition than the chlorine (Cl₂) gas into the gas process chamber 109. The peripheral portions of the wafers 130 are mainly etched using the chlorine (Cl₂) gas having a high decomposition rate and the central parts of the wafers 130 are mainly etched using the hydrogen chloride (HCl) gas having a low decomposition rate, thereby improving etching uniformity in the planes of the wafers 130.

Also, etching uniformity between the wafers 130 may be improved. As described above, at the upper end of the boat 105, the peripheral portions of the wafers 130 are etched using the chlorine (Cl₂) gas having a high decomposition rate. Thus, most of the chlorine (Cl₂) gas is consumed at the upper end of the boat 105 and the amount of the remaining chlorine (Cl₂) gas is insufficient at the lower end of the boat 105. Thus, at the lower end of the boat 105, the wafers 130 are etched by promoting the decomposition of the hydrogen chloride (HCl) gas to generate chlorine radicals from the hydrogen chloride (HCl) gas and supplying the chlorine radicals to supplement for the deficiency of the chlorine (Cl₂) gas. As described above, the speed of etching may be prevented from decreasing at the lower end of the boat 105, and the etching uniformity between wafers 130 may be improved.

[Purging Process (S70), Atmospheric Pressure Recovery Process (S80)]

After the etching of the wafers 130 is completed, the purging process (S70) is performed.

First, the supply of the chlorine (Cl₂) gas, the hydrogen chloride (HCl) gas and the hydrogen (H₂) gas into the process chamber 109 is suspended by closing the valve 201c of the first gas supply pipe 201a, the valve 201f of the first carrier gas supply pipe 201d, the valve 202c of the second gas supply pipe 202a and the valve 202f of the second carrier gas supply pipe 202d. Then, the valve 201f of the first carrier gas supply pipe 201d is opened to supply an inert gas, e.g., nitrogen (N₂) gas, into the first carrier gas supply pipe 201d. The flow rate of the nitrogen (N₂) gas flowing through the first carrier gas supply pipe 201d is adjusted by the MFC 201e. The inert gas, the flow rate of which is adjusted, is exhausted via the gas exhaust pipe 116 while being supplied to the region between the upper end of the boat 105 and the upper end of the reaction tube 103 via the front end of the first nozzle 201. By supplying the inert gas into the process chamber 109, the etching gases, i.e., the chlorine (Cl₂) gas, the hydrogen chloride (HCl) gas and the chlorine radicals, and the etching reaction material which remain in the process chamber 109 are exhausted via the gas exhaust pipe 116, together with the inert gas, after the etching process (S60) is completed.

As described above, the inside of the process chamber 109 is purged and the atmosphere in the process chamber 109 is replaced with the inert gas [purging process (S70)]. After the purging of the inside of the process chamber 109 is completed, the inert gas is supplied into the process chamber 109 and the pressure in the process chamber 109 is returned to atmospheric pressure by adjusting the degree of opening of the APC valve 116b of the gas exhaust pipe 116 [atmospheric pressure recovery process (S80)]. Although in the current embodiment, the inert gas is supplied into the process chamber 109 using the first nozzle 201 and the second nozzle 202, the inert gas may be supplied into the process chamber 109 using at least one of the first nozzle 201 and the second nozzle 202.

[Boat Unloading Process (S90) to Wafer Unloading Process (S110)]

Then, the rotation of the wafer 130 is suspended, the seal cap 219 is moved downward by the boat elevator 115 to open the lower end of the inlet flange 118, and the boat 105 is moved below the inlet flange 118 to unload the boat 105 outside the reaction tube 103 [boat unloading process (S90)]. Then, the wafers 130 placed in the boat 105 are in standby until the wafers 130 are cooled [wafer temperature lowering process (S100)]. After the wafers 130 are cooled, the processed wafers 130 are unloaded from the boat 105 by the wafer transfer mechanism 151 and are then transferred to the wafer cassette 152 [wafer unloading process (S110)]. By performing these processes S10 to S110, the substrate processing process according to the current embodiment is completed.

(3) Advantages of the Current Embodiment

According to the current embodiment, at least one of the following advantages may be achieved.

(a) According to the current embodiment, during the etching process (S60), chlorine (Cl₂) gas is supplied via the first nozzle 201 and hydrogen chloride (HCl) gas is supplied via the second nozzle 202, toward a region between upper end of the boat 105 and the upper end of the process chamber 109 in the process chamber 109. The chlorine (Cl₂) gas having a high decomposition rate is decomposed as soon as it is supplied into the process chamber 109, thereby generating chlorine radicals having high reactivity. Thus, when the chlorine (Cl₂) gas arrives at the gap regions between the adjacent wafers 130, the peripheral portions of the wafers 130 are mainly etched using the chlorine (Cl₂) gas and the central parts of the wafers 130 are etched using a portion of chlorine radicals. The hydrogen chloride (HCl) gas having a low decomposition rate is not immediately decomposed even when it is supplied into the process chamber 109, and most of the hydrogen chloride (HCl) gas passes through the peripheral portions of the wafers 130 and arrives at the central parts of the wafers 130 when the hydrogen chloride (HCl) gas flows to the gap regions between the wafers 130. A portion of the hydrogen chloride (HCl) gas is not only thermally decomposed at the central parts of the wafers 130 to generate chlorine radicals but is also decomposed through thermal decomposition of the chlorine radicals generated from the chlorine (Cl₂) gas flowing to the central parts of the wafers 130, thereby generating chlorine radicals from the hydrogen chloride (HCl) gas. The chlorine radicals generated from the hydrogen chloride (HCl) gas are mainly used to etch the central parts of the wafers 130 and only a portion of the chlorine radicals are used to etch the peripheral portions of the wafers 130. As described above, even when a plurality of the wafers 130 are stacked, the peripheral portions and central parts of the wafers 130 may be etched, thereby improving etching uniformity in the planes of the wafers 130 (planes of the substrates).

(b) According to the current embodiment, the etching gases supplied into the process chamber 109 flow from the upper end (or one end) of the boat 105 to the lower end (or the other end) of the boat 105. A portion of chlorine radicals generated from the chlorine (Cl₂) gas and the hydrogen chloride (HCl) gas are used to etch the wafers 130 at the upper end (or one end) of the boat 105 in the substrate accommodating region 106, and at least a portion of the remaining chlorine radicals are used to etch the wafers 130 at the lower end (or the other end) of the boat 105 in the substrate accommodating region 106. Also, the hydrogen chloride (HCl) gas is thermally decomposed at the lower end of the boat 105 to generate chlorine radicals from the hydrogen chloride (HCl) gas, and the chlorine radicals are supplied to supplement for the deficiency of the chlorine radicals generated from the chlorine (Cl₂) gas. As described above, since the chlorine radicals generated from the hydrogen chloride (HCl) gas and the chlorine radicals generated from the chlorine (Cl₂) gas are used to etch the wafers 130 at the lower end of the boat 105, the etching uniformity between the wafers 130 at the upper end of the boat 105 and the wafers 130 at the lower end of the boat 105 (i.e., between the substrates) may be improved.

(c) According to the current embodiment, since the wafers 130 are etched by simultaneously supplying two types of etching gases, e.g., the chlorine (Cl₂) gas and hydrogen chloride (HCl) gas, the amount of etching increases and the speed of etching is higher than when only one type of etching gas is used.

(d) According to the current embodiment, the wafers 130 are etched by setting an inner temperature of the process chamber 109 to be less than 700° C. by appropriately controlling the amount of current to be supplied to the heater 101 (including the heaters 101a, 101b, 101c, 101d and 101e). As described above, the decomposition of the hydrogen chloride (HCl) gas may be suppressed until the hydrogen chloride (HCl) gas flows to the central parts of the wafers 130, and may then be efficiently performed at the central parts of the wafers 130. Also, damage to the wafer 130 may be reduced when the wafers are etched by suppressing the amount of heat to be supplied to the wafers 130. Also, a plasma generation source, for example, using expensive electrodes does not need to be installed. Thus, the performances of the members disposed in the process chamber 109 may be prevented from being degraded due to plasma generated from the plasma generation source, and particles and pollutants may be prevented from being generated due to degradation in the performances of the members.

(4) Embodiments of the Present Invention

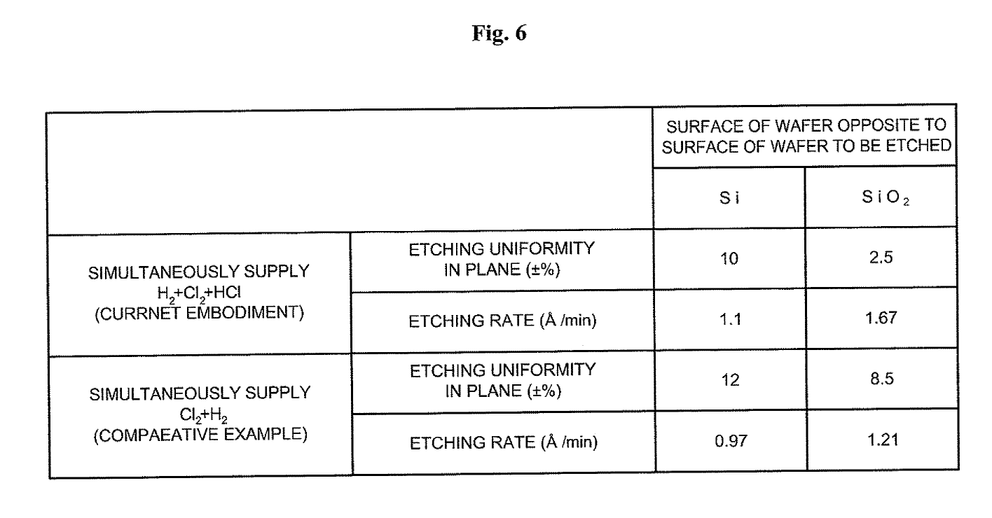

A result of measurement that exhibits the advantages according to the current embodiment will now be described. FIG. 6 is a view illustrating a result of measuring etching uniformity and an etching rate. FIG. 6 compares a case in which chlorine (Cl₂) gas and hydrogen chloride (HCl) gas are used as etching gases (current embodiment) with a case in which only the chlorine (Cl₂) gas is used as an etching gas (comparative example). Both in the current embodiment and the comparative example, hydrogen (H₂) gas is used as a carrier gas. The current embodiment and the comparative example will also be described with respect to a case in which a surface of a wafer opposite to a surface of the wafer to be etched (the opposite surface) is a silicon (Si) surface or a silicon dioxide (SiO₂) surface. The data included in the table of FIG. 6 was obtained under various conditions, e.g., when, in a process chamber, a temperature was 650° C., pressure was 50 Pa or less, the flow rate of the chlorine (Cl₂) gas was 100 sccm or less, and the flow rate of the hydrogen chloride (HCl) gas was 300 sccm or less.

Referring to FIG. 6, the etching uniformity and speed of etching in a plane of the wafer were better when both the chlorine (Cl₂) gas and the hydrogen chloride (HCl) gas were used (current embodiment) than when only the chlorine (Cl₂) gas was used (comparative example). In FIG. 6, the etching uniformity in the plane of the wafer denotes the degree of regularities in the plane of the wafer. In other words, it means that the plane of the wafer has a concavo-convex shape when the etching uniformity in the plane of the wafer is large, and means that the plane of the wafer has a smooth surface when the etching uniformity in the plane of the wafer is small. Also, the etching uniformity and speed of etching in the plane of the wafer when the opposite surface was the silicon dioxide (SiO₂) surface were better than when the opposite surface was the silicon (Si) surface.

### Second Embodiment of the Present Invention

Next, the second embodiment of the present invention will be described. In the current embodiment, hydrogen chloride (HCl) gas (second etching gas) is supplied via multi-system nozzles so that the number of locations (predetermined locations) to which the hydrogen chloride (HCl) gas is supplied may be increased, unlike in the first embodiment. The other configurations in the second embodiment are the same as those in the first embodiment. In the current embodiment, the wafers 130 are etched by exhausting the inside of the process chamber 109 via the lower end (or the other end) of the substrate accommodating region 106 configured to receive the plurality of stacked wafers 130 in the process chamber 109 while supplying chlorine (Cl₂) gas and hydrogen chloride (HCl) gas via the upper end (or one end) of the substrate accommodating region 106, and further supplying the hydrogen chloride (HCl) gas via a predetermined location between the upper and lower ends (one end and the other end) of the substrate accommodating region 106.

The reason for which the hydrogen chloride (HCl) gas is supplied via the multi-system nozzles will now be described. In the process chamber 109, etching gases, i.e., the chlorine (Cl₂) gas and the hydrogen chloride (HCl) gas, and chlorine radicals, mainly flow in a stacking direction of the wafers 130, i.e., a direction from the top of the boat 105 (or the substrate accommodating region 106) to the bottom thereof. Thus, it may be difficult for the etching gases and the chlorine radicals to arrive at a side lower than the upper end of the boat 105, i.e., the mid-stream side and the downstream side of the gas flow, thereby supplying insufficient amounts of the etching gases and the chlorine radicals to the gap regions between the wafers 130. In this case, the speed of etching the central parts of the wafers 130 becomes slow, and thus the wafers 130 cannot be evenly etched. In particular, chlorine radicals are generated from the chlorine (Cl₂) gas having a high decomposition rate as soon as the chlorine (Cl₂) gas is supplied into the process chamber 109. Thus, most of the chlorine radicals generated from the chlorine (Cl₂) gas are consumed at the upper end of the boat 105 and a sufficient amount of the chlorine radicals may be supplied to the lower end of the boat 105.

For this reason, in the current embodiment, the hydrogen chloride (HCl) gas is further supplied between the upper and lower ends of the boat 105 during the process, and sufficient amounts of the etching gases and the chlorine radicals are supplied to the gap regions between the wafers 130, thereby improving the etching uniformity in the planes of the wafers 130. Also, the etching is promoted at the mid-stream side and the downstream side by further supplying the hydrogen chloride (HCl) gas to supplement for the deficiency of the chlorine (Cl₂) gas, thereby improving the etching uniformity between the wafers 130.

(1) Substrate Processing Apparatus

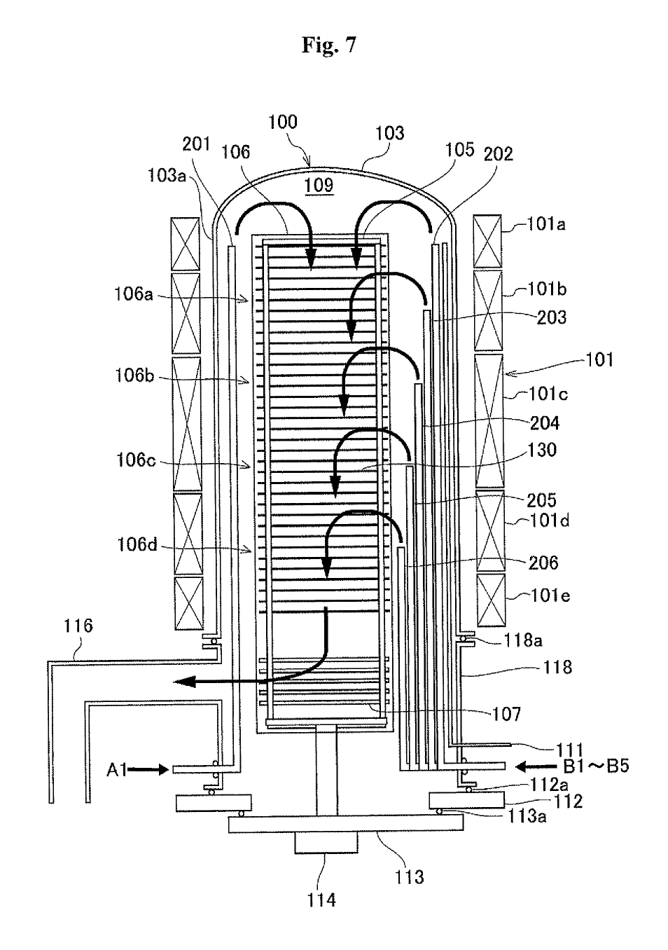

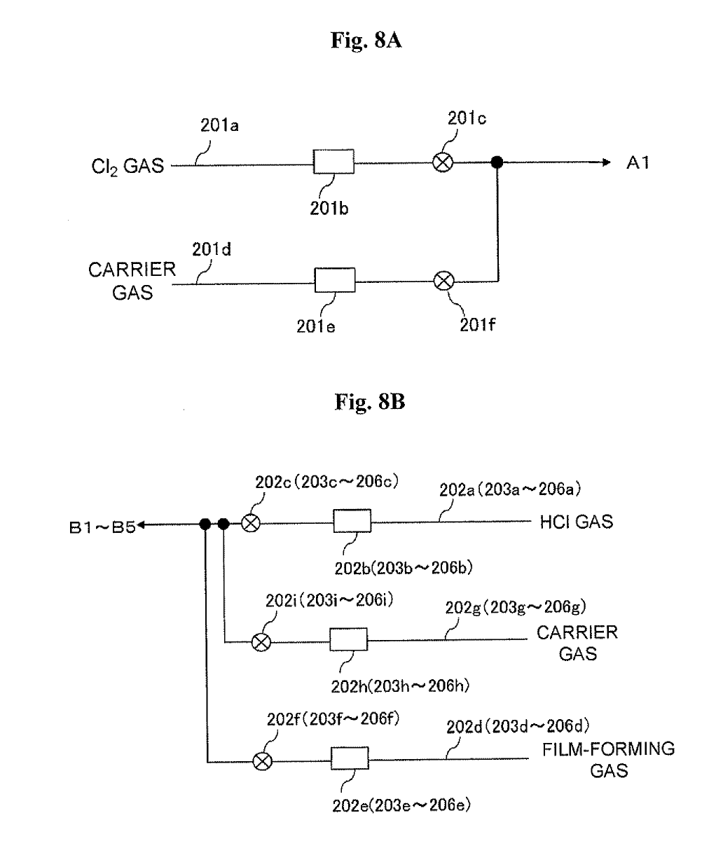

FIG. 7 is a schematic configuration diagram of a process chamber 109 according to the second embodiment of the present invention. FIGS. 8A and 8B are schematic configuration diagrams of a gas supply system according to the second embodiment of the present invention. Referring to FIG. 7, in the current embodiment, in an inlet flange 118, not only a first nozzle 201 and a second nozzle 202 but also a third nozzle 203, a fourth nozzle 204, a fifth nozzle 205 and a sixth nozzle 206 that supplies hydrogen chloride (HCl) gas (second etching gas) into the process chamber 109 are installed. The third to sixth nozzles 203 to 206 each have the same configuration as those of the first nozzle 201 and the second nozzle 202.

Locations of front ends of the third to sixth nozzles 203 to 206 are respectively determined as a plurality of mid-points having different positions (or heights) in the region between a boat 105 and sidewalls 103a of a reaction tube 103, according to the stacking direction of the wafers 130. For example, the front ends of the third to sixth nozzles 203 to 206 are respectively disposed at predetermined locations near an upper portion 106a, a central upper portion 106b, a central lower portion 106c and a lower portion 106d of the substrate accommodating region 106, and the location of the front end of each of the third to sixth nozzles 203 to 206 is configured to be lowered whenever each of the third to sixth nozzles 203 to 206 faces the sixth nozzle 206. As illustrated in FIGS. 8A and 813, upstream ends of the third to sixth nozzles 203 to 206 are connected to downstream sides of third to sixth gas supply pipes 203a to 206a, respectively. Also, as in the first embodiment, MFCs 203b to 206b which are flow rate controllers (flow rate control units), and valves 203c to 206c which are switch valves are sequentially installed in the third to sixth gas supply pipes 203a to 206a in an upstream direction, respectively.

Downstream ends of third to sixth carrier gas supply pipes 203d to 206d are connected at downstream sides of the valves 203c to 206c of the third to sixth gas supply pipes 203a to 206a, respectively. In the third to sixth carrier gas supply pipes 203d to 206d, MFCs 203e to 206e which are flow rate controllers (flow rate control units) and valves 203f to 206f which are switch valves are sequentially installed in the upstream direction. Also, downstream ends of second to fifth film-forming gas supply pipes 203g to 206g are connected at the downstream sides of the valves 203c to 206c of the third to sixth gas supply pipes 203a to 206a, respectively. In the second to fifth film-forming gas supply pipes 203g to 206g, MFCs 203h to 206h which are flow rate controllers (flow rate control units) and valves 203i to 206i which are switch valves are respectively installed in the upstream direction.

A controller according to the current embodiment is connected to the MFCs 203b to 206b and the valves 203c to 206c of the third to sixth gas supply pipes 203a to 206a, the MFCs 203e to 206e and the valves 203f to 206f of the third to sixth carrier gas supply pipes 203d to 206d, and the MFCs controller 203h to 206h and the valves 203i to 206i of the second to fifth film-forming gas supply pipes 203g to 206g, and are configured to control them so as to adjust the amounts of gas supplied to the third nozzle 203 to the sixth nozzle 206.

(2) Substrate Processing Process

Next, a substrate processing process performed by the substrate processing apparatus configured as described will be described. Descriptions of the substrate processing process according to the second embodiment that are the same as those of the substrate processing process according to the first embodiment will not be described again here, and only the etching process (S60) of FIG. 4 will be described.

In the etching process (S60), hydrogen chloride (HCl) gas is supplied into the process chamber 109 via the second nozzle 202 while chlorine (Cl₂) gas is supplied into the process chamber 109 via the first nozzle 201, as in the first embodiment. Also, the hydrogen chloride (HCl) gas is supplied to a region having a circular arc shape between the upper portion 106a of a substrate accommodating region 106 (or the boat 105) and the sidewalls 103a of the reaction tube 103 via the third nozzle 203, is supplied to a region having a circular arc shape between the central upper portion 106b of the substrate accommodating region 106 and the sidewalls 103a of the reaction tube 103 via the fourth nozzle 204, is supplied to a region having a circular arc shape between the central lower portion 106c of the substrate accommodating region 106 and the sidewalls 103a of the reaction tube 103 via the fifth nozzle 205, and is supplied to a region having a circular arc shape between the lower portion 106d of the substrate accommodating region 106 and the sidewalls 103a of the reaction tube 103 via the sixth nozzle 206.

The hydrogen chloride (HCl) gas supplied via the third nozzle 203 mainly arrives at a gap region between the wafers 130 at an upper portion of the boat 105 (or, the upper portion 106a of the substrate accommodating region 106). The hydrogen chloride (HCl) gas supplied via the fourth nozzle 204 mainly arrives at a gap region between the wafers 130 at a central upper portion of the boat 105 (or the central upper portion 106h of the substrate accommodating region 106). The hydrogen chloride (HCl) gas supplied via the fifth nozzle 205 mainly arrives at a gap region between the wafers 130 at a central lower portion of the boat 105 (or the central lower portion 106c of the substrate accommodating region 106). The hydrogen chloride (HCl) gas supplied via the sixth nozzle 206 mainly arrives at a gap region between the wafers 130 at a lower portion of the boat 105 (or the lower portion 106d of the substrate accommodating region 106). Most of the hydrogen chloride (HCl) gas arriving at the gap regions passes through the peripheral portions of the wafers 130 and flows to the central parts of the wafers 130. The hydrogen chloride (HCl) gas is supplied to the central parts of the wafers 130 as described above.

In the current embodiment, the amount of the hydrogen chloride (HCl) gas supplied via the second nozzle 202 is controlled to be greater than those of the hydrogen chloride (HCl) gas supplied via the third nozzle 203 to sixth nozzle 206. The amount of the hydrogen chloride (HCl) gas supplied via each of the third nozzle 203 to the sixth nozzle 206 becomes reduced as each of the third nozzle 203 to the sixth nozzle 206 approaches the sixth nozzle 206, so that the deficiency of the etching gases supplied to the lower end of the boat 105 may be appropriately supplemented.

(3) Advantages of the Current Embodiment

According to the current embodiment, not only the advantages according to the first embodiment but also at least one of the following advantages may be achieved.

Specifically, according to the current embodiment, the hydrogen chloride (HCl) gas is further supplied between the upper and lower ends of the boat 105 during the process, thereby supplementing the deficiency of the etching gases supplied to the lower end of the boat 105. As described above, the speed of etching is increased by supplying a sufficient among of chlorine radicals, which are generated from the hydrogen chloride (HCl) gas, to etch the central parts of the wafers 130, and the etching uniformity between the wafers 130 may thus be greatly improved.

Also, an amount of the hydrogen chloride (HCl) gas to be supplied into the process chamber 109 is appropriately controlled by increasing an amount of the hydrogen chloride (HCl) gas supplied via the second nozzle 202 compared to those of the hydrogen chloride (HCl) gas supplied via the third nozzle 203 to the sixth nozzle 206 and by reducing the amount of the hydrogen chloride (HCl) gas supplied via each of the third nozzle 203 to the sixth nozzle 206 as each of the third nozzle 203 to the sixth nozzle 206 approaches the sixth nozzle 206. The speeds of etching the wafers 130 may be controlled to be the same as described above, thereby greatly improving the etching uniformity between the wafers 130.

### Third Embodiment of the Present Invention

Next, the third embodiment of the present invention will be described. The current embodiment is differentiated from the first and second embodiments in that chlorine (Cl₂) gas (second etching gas) is supplied via multi-system nozzles to increase the number of locations (predetermined locations) to which the chlorine (Cl₂) gas is supplied. The other features of the third embodiment are the same as operations of the process furnace 100 according to the first embodiment. Specifically, according to the current embodiment, the wafers 130 (substrates) are etched by exhausting the inside of the process chamber via the lower end (the other end) of the substrate accommodating region 106 configured to receive the plurality of stacked wafers 130 in the process chamber 109 while supplying chlorine (Cl₂) gas and hydrogen chloride (HCl) gas via the upper end (or one end) of the substrate accommodating region 106, and further supplying the chlorine (Cl₂) gas via a predetermined location between the upper end (or one end) and the lower end (or the other end) of the substrate accommodating region 106.

The reason for which the chlorine (Cl₂) gas is supplied via the multi-system nozzles will now be described. Chlorine radicals are generated from the chlorine (Cl₂) gas having a high decomposition rate as soon as the chlorine (Cl₂) gas is supplied into the process chamber 109. Thus, most of the chlorine radicals generated from the chlorine (Cl₂) gas are consumed at the upper end of the boat 105, and the chlorine (Cl₂) gas may thus be deficient at the lower end of the boat 105. Thus, according to the current embodiment, the deficiency of the etching gases is supplemented by further supplying the hydrogen chloride (HCl) gas between the upper and lower ends of the boat 105 during the process so as to perform etching at the midstream and downstream sides of gas flow, thereby improving the etching uniformity between the wafers 130. Also, a sufficient amount of the chlorine (Cl₂) gas is supplied to the gap regions between the wafers 130, thereby improving the etching uniformity in the planes of the wafers 130.

(1) Substrate Processing Apparatus

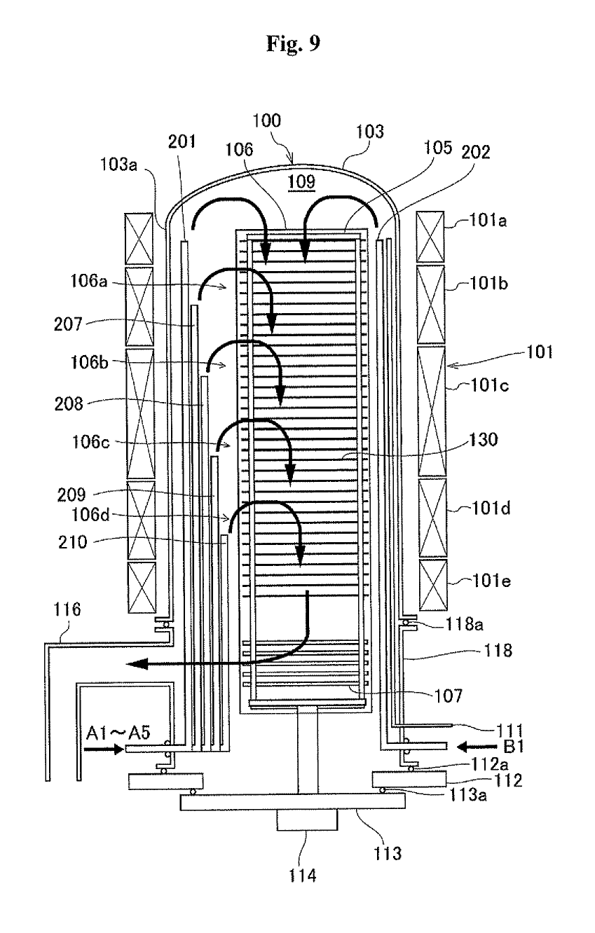

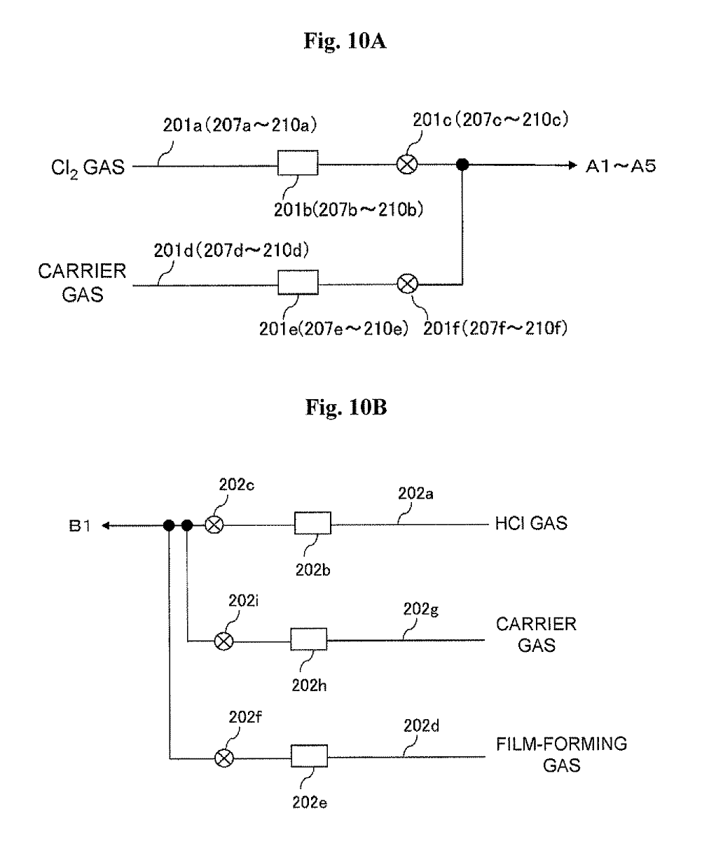

FIG. 9 is a schematic configuration diagram of a process chamber 109 according to the third embodiment of the present invention. FIGS. 10A and 10B are schematic configuration diagrams of a gas supply system according to the third embodiment of the present invention. According to the current embodiment, as illustrated in FIG. 9, in an inlet flange 118, a first nozzle 201, a second nozzle 202, a seventh nozzle 207, an eighth nozzle 208, a ninth nozzle 209 and a tenth nozzle 210 that supply chlorine (Cl₂) gas (first etching gas) into the process chamber 109 are installed. The seventh nozzle 207 to the tenth nozzle 210 each have the same configuration as the first nozzle 201 and the second nozzle 202.

Locations of front ends of the seventh to tenth nozzles 207 to 210 are respectively determined as a plurality of mid-points having different positions (or heights) in a region between a boat 105 and sidewalls 103a of a reaction tube 103, according to the stacking direction of wafers 130. For example, the front ends of the seventh to tenth nozzles 207 to 210 are respectively disposed at predetermined locations near an upper portion 106a, a central upper portion 106b, a central lower portion 106c, and a lower portion 106d of the substrate accommodating region 106, and the location of the front end of each of the seventh to tenth nozzles 207 to 210 is configured to be lowered whenever facing the tenth nozzle 210. As illustrated in FIG. 10A, upstream ends of the seventh to tenth nozzles 207 to 210 are connected to downstream sides of seventh to tenth gas supply pipes 207a to 210a, respectively. Also, as in the first embodiment, MFCs 207b to 210b which are flow rate controllers (flow rate control units), and valves 207c to 210c which are switch valves are sequentially installed in the seventh to tenth gas supply pipes 207a to 210a in an upstream direction, respectively.

Downstream ends of seventh to tenth carrier gas supply pipes 207d to 210d are connected at downstream sides of the valves 207c to 210c of tenth gas supply pipes 207a to 210a, respectively. In the seventh to tenth carrier gas supply pipes 207d to 210d, MFCs 207e to 210e which are flow rate controllers (flow rate control units) and valves 207f to 210f which are switch valves are sequentially installed in the upstream direction.

A controller according to the current embodiment is connected to the MFCs 207b to 210b and the valves 207c to 210c of the tenth gas supply pipes 207a to 210a and the MFCs 207e to 210e and the valve 207f to 210f of the seventh to tenth carrier gas supply pipes 207d to 210d, and are configured to control them so as to adjust the amount of gas to be supplied to the seventh nozzle 207 to the tenth nozzle 210.

(2) Substrate Processing Process

Next, a substrate processing process performed by the substrate processing apparatus configured as described will be described. Descriptions of the substrate processing process according to the third embodiment that are the same as those of the substrate processing process according to the first embodiment will not be described again here, and only the etching process (S60) of FIG. 4 will be described.

In the etching process (S60), hydrogen chloride (HCl) gas is supplied into the process chamber 109 via the second nozzle 202 while chlorine (Cl₂) gas is supplied into the process chamber 109 via the first nozzle 201, as in the first embodiment. Also, the chlorine (Cl₂) gas is supplied to a region having a circular arc shape between the upper portion 106a of the substrate accommodating region 106 (or the boat 105) and the sidewalls 103a of the reaction tube 103 via the seventh nozzle 207, is supplied to a region having a circular arc shape between the central upper portion 106b of the substrate accommodating region 106 and the sidewalls 103a of the reaction tube 103 via the eighth nozzle 208, is supplied to a region having a circular arc shape between the central lower portion 106c of the substrate accommodating region 106 and the sidewalls 103a of the reaction tube 103 via the ninth nozzle 209, and is supplied to a region having a circular arc shape between the lower portion 106d of the substrate accommodating region 106 and the sidewalls 103a of the reaction tube 103 via the tenth nozzle 210.

In the current embodiment, the amount of the chlorine (Cl₂) gas supplied via the first nozzle 201 is controlled to be greater than those of the chlorine (Cl₂) gas supplied via the seventh to tenth nozzles 207 to 210. Also, substantially the same amount of the chlorine (Cl₂) gas may be controlled to be supplied via the seventh to tenth nozzles 207 to 210

The chlorine (Cl₂) gas supplied via the seventh nozzle 207 is directly thermally decomposed to generate chlorine radicals, and the chlorine radicals arrive at the gap regions between the wafers 130 at an upper portion of the boat 105 (or the upper portion 106a of the substrate accommodating region 106). The chlorine (Cl₂) gas supplied via the eighth nozzle 208 is directly thermally decomposed to generate chlorine radicals, and the chlorine radicals arrive at the gap regions between the wafers 130 at a central upper portion of the boat 105 (or the central upper portion 106b of the substrate accommodating region 106). The chlorine (Cl₂) gas supplied via the ninth nozzle 209 is directly thermally decomposed to generate chlorine radicals, and the chlorine radicals arrive at the gap regions between the wafers 130 at a central lower portion of the boat 105 (the central lower portion 106c of the substrate accommodating region 106). The chlorine (Cl₂) gas supplied via the tenth nozzle 210 is directly thermally decomposed to generate chlorine radicals, and the chlorine radicals arrive at the gap regions between the wafers 130 at a lower portion of the boat 105 (or the lower portion 106d of the substrate accommodating region 106). Most of the chlorine radicals arriving the gap regions are consumed to etch the peripheral portions of the wafers 130 and the remaining chlorine radicals flow to the central parts of the wafers 130.

(3) Advantages of the Current Embodiment

According to the current embodiment, not only the advantages according to the first embodiment but also at least one of the following advantages may be achieved.

According to the current embodiment, the deficiency of the etching gases at the lower end of the boat 105 is supplemented by supplying the chlorine (Cl₂) gas between the upper and lower ends of the boat 105 during the process. As described above, since sufficient amounts of etching gases may be supplied to the wafers 130, the etching uniformity between the wafers 130 may be greatly improved.

Also, the amount of the chlorine (Cl₂) gas supplied via the first nozzle 201 is controlled to be greater than those of the chlorine (Cl₂) gas supplied via the seventh nozzle 207 to the tenth nozzle 210, and substantially the same amount of the chlorine (Cl₂) gas is controlled to be supplied via the seventh nozzle 207 to the tenth nozzle 210. As described above, the speeds of etching the wafer 130 may be more precisely uniformized and the etching uniformity between the wafers 130 may be greatly improved by appropriately supplying the chlorine (Cl₂) gas, which is likely to be directly consumed as soon as it is decomposed, during the process.

Also, according to the current embodiment, sufficient amounts of the chlorine (Cl₂) gas and the chlorine radicals may be supplied to the gap regions between the wafers 130 by supplying the chlorine (Cl₂) gas during the process. Thus, the speed of etching the central parts of the wafers 130 may be increased and the etching uniformity between the wafers 130 may be greatly improved.

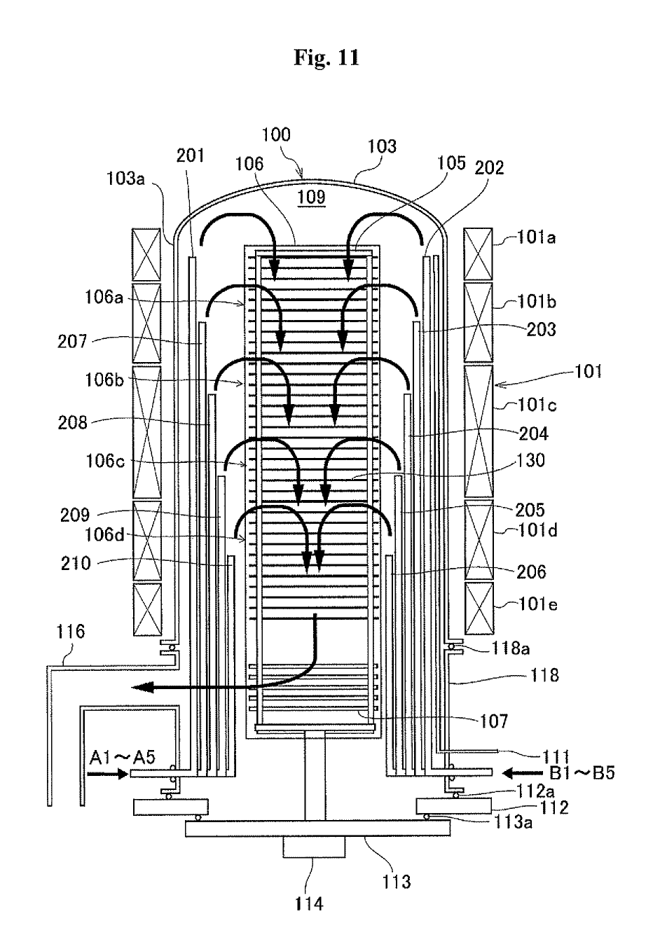

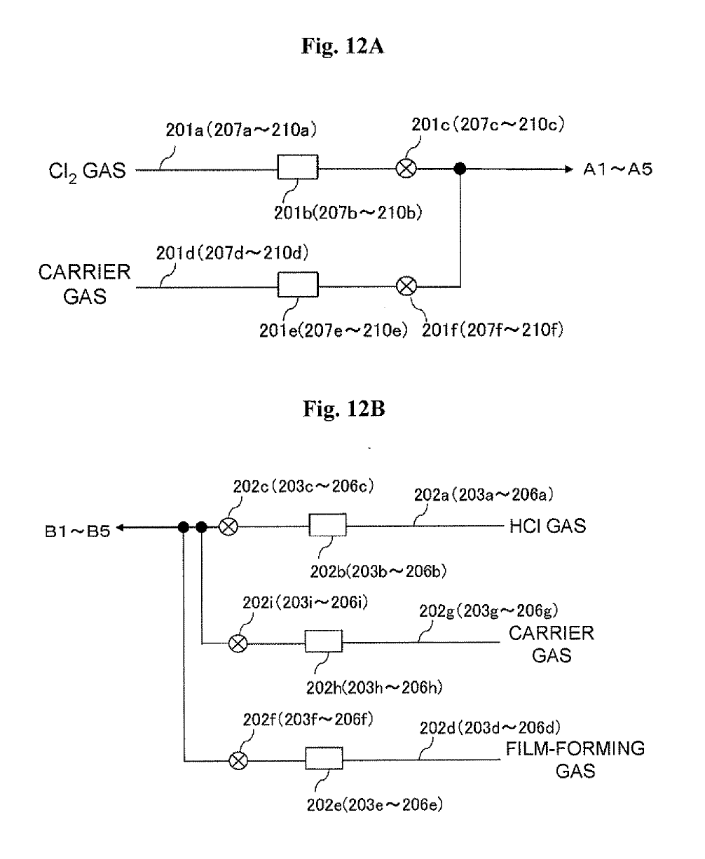

It may be efficient to improve the etching uniformity when a combination of the second and third embodiments is performed. FIG. 11 is a schematic configuration diagram of a process chamber 109 according to a combination of the second and third embodiments of the present invention. FIGS. 12A and 12B are schematic configuration diagrams of a gas supply system according to a combination of the second and third embodiments of the present invention.

In the configurations illustrated in FIGS. 11, 12A and 12B, the wafers 130 are etched by exhausting the inside of the process chamber 109 via the lower end (the other end) of the substrate accommodating region 106 configured to accommodate a plurality of stacked wafers 130 in the process chamber 109 while chlorine (Cl₂) gas and hydrogen chloride (HCl) gas are supplied via the upper end (one end) of the substrate accommodating region 106, and further supplying the chlorine (Cl₂) gas and the hydrogen chloride (HCl) gas via a predetermined location between the upper and lower ends (one end and the other end) of the substrate accommodating region 106.

According to this configuration, the chlorine (Cl₂) gas and the hydrogen chloride (HCl) gas that are further supplied between the upper end and the lower end of the boat 105 during the process may be more appropriately controlled. Thus, not only the etching uniformity in the planes of the wafers 130 but also the etching uniformity between the wafers 130 may be greatly improved.

### Fourth Embodiment of the Present Invention

Next, the fourth embodiment of the present invention will be described. The current embodiment is different from the first to third embodiments in that a plurality of gas supply holes (plurality of gas supply holes) are formed in nozzles for supplying chlorine (Cl₂) gas and hydrogen chloride (HCl) gas. The other configurations of the current embodiment are the same as operations of the process furnace 100 according to the first embodiment. That is, according to the current embodiment, by forming the plurality of gas supply holes in the nozzles in a stacking direction of the wafers 130, the wafers 130 may be etched by supplying the chlorine (Cl₂) gas and the hydrogen chloride (HCl) gas via predetermined locations between the upper and lower ends of the boat 105.

(1) Substrate Processing Apparatus

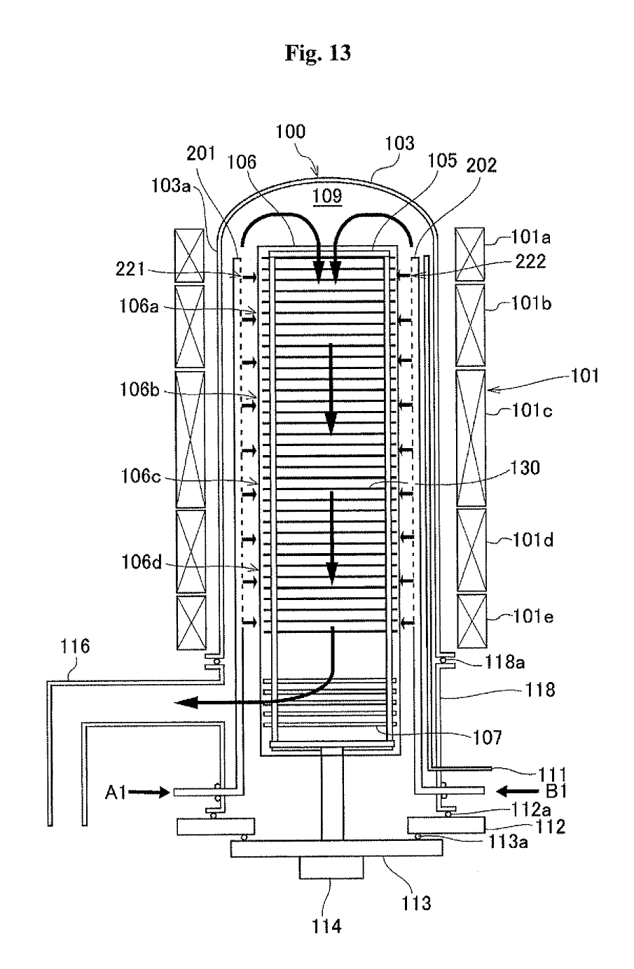

FIG. 13 is a schematic configuration diagram of a process chamber 109 according to a fourth embodiment of the present invention. A gas supply system according to the current embodiment is substantially the same as that illustrated in FIG. 2. Referring to FIG. 13, in a first nozzle 201, a plurality of gas supply holes 221 are formed in a extending direction of the first nozzle 201 (stacking direction of the wafers 130). The plurality of gas supply holes 221 are formed to respectively correspond to the wafers 130 placed in the boat 105, and configured to supply gases to gap regions between wafers 130 corresponding thereto. In detail, each of the plurality of gas supply holes 221 is formed between an intersection of a corresponding wafer 130 and the first nozzle 201 when the corresponding wafer 130 extends in the extending and an intersection of a wafer 130 adjacent to a main surface of the corresponding wafer 130 and the first nozzle 201 when the adjacent wafer 130 extends in the extending direction.

In a second nozzle 202, a plurality of gas supply holes 222 are formed in the extending direction (stacking direction of the wafers 130). The plurality of gas supply holes 222 are formed to respectively correspond to the wafers 130 placed in the boat 105, and configured to supply gases to gap regions between wafers 130 corresponding thereto. In detail, each of the plurality of gas supply holes 222 is formed between an intersection of a corresponding wafer 130 and the second nozzle 202 when the corresponding wafer 130 extends in the extending direction and an intersection of a wafer 130 adjacent to a main surface of the corresponding wafer 130 and the second nozzle 202 when the adjacent wafer 130 extends in the extending direction.

(2) Substrate Processing Process

Next, a substrate processing process performed by the substrate processing apparatus configured as described will be described. Descriptions of the substrate processing process according to the fourth embodiment that are the same as those of the substrate processing process according to the first embodiment will not be described again here, and only the etching process (S60) of FIG. 4 will be described.

In the etching process (S60), as in the first embodiment, hydrogen chloride (HCl) gas is supplied into the process chamber 109 via the front end of the second nozzle 202 while chlorine (Cl₂) gas is supplied into the process chamber 109 via the front end of the first nozzle 201. Also, the hydrogen chloride (HCl) gas is directly supplied to the gap regions between the wafers 130 via the gas supply holes 222 of the second nozzle 202 while the chlorine (Cl₂) gas is directly supplied to the gap regions between the wafers 130 via the gas supply holes 221 of the first nozzle 201.

The chlorine (Cl₂) gas supplied via the gas supply holes 221 is directly thermally decomposed to generate chlorine radicals. Most of the generated chlorine radicals substantially vertically arrive at a gap region between the wafers 130 corresponding to each of the gas supply holes 221. Most of the chlorine radicals arriving at the gap regions are consumed to etch the peripheral portions of the wafers 130 and the remaining chlorine radicals flow to the central parts of the wafers 130.

Most of the hydrogen chloride (HCl) gas supplied via the gas supply holes 222 substantially vertically arrives at a gap region between the wafers 130 corresponding to each of the gas supply holes 222. Most of the hydrogen chloride (HCl) gas directly passes through the peripheral portions of the wafers 130 and then flows to the central parts of the wafers 130. At the central parts of the wafers 130, thermal decomposition of the hydrogen chloride (HCl) gas is promoted due to the chlorine radicals, thereby generating chlorine radicals from the hydrogen chloride (HCl) gas. Also, a portion of heated hydrogen chloride radicals are thermally decomposed to generate chlorine radicals. The chlorine radicals generated at the central parts of the wafers 130 are mainly consumed to etch the central parts of the wafers 130.

Also, the chlorine (Cl₂) gas and the hydrogen chloride (HCl) gas supplied via the gas supply holes 221 and 222 may be used in not only a direction perpendicular to the gap regions between the wafers 130 but also directions having a range of angles that are less than 45° with respect to the perpendicular direction. Thus, a portion of the chlorine (Cl₂) gas and the hydrogen chloride (HCl) gas supplied to a portion of gap regions between the wafers 130 may arrive at gap regions adjacent thereto.

(3) Advantages of the Current Embodiment

According to the current embodiment, not only the advantages according to the first embodiment but also at least one of the following advantages may be achieved.

According to the current embodiment, by forming the plurality of gas supply holes 221 in the first nozzle 201 in the extending direction (in the stacking direction of the wafers 130), the chlorine (Cl₂) gas is further supplied between the upper and lower ends of the boat 105 during the process, and the deficiency of the etching gases consumed near the upper end of the boat 105 is supplemented. Also, by forming the plurality of gas supply holes 222 in the second nozzle 202 in the extending direction (in the stacking direction of the wafers 130), the hydrogen chloride (HCl) gas is further supplied between the upper and lower ends of the boat 105 during the process, and the deficiency of the etching gases consumed near the upper end of the boat 105 is supplemented. As described above, a sufficient amount of etching gases may be supplied to the gap regions between the wafers 130, thereby greatly improving the etching uniformity between the wafers 130.

Also, according to the current embodiment, the chlorine (Cl₂) gas and the hydrogen chloride (HCl) gas are further supplied between the upper and lower ends of the boat 105, thereby guaranteeing supply of sufficient amounts of the chlorine (Cl₂) gas, the hydrogen chloride (HCl) gas, and the chlorine radicals to the gap regions between the wafers 130. Thus, the speed of etching the central parts of the wafers 130 may be increased, and the etching uniformity in the planes of the wafers 130 may be greatly improved.

Also, in the current embodiment, each of the plurality of gas supply holes 221 is configured to be formed between an intersection of a corresponding wafer 130 and the first nozzle 201 when the corresponding wafer 130 extends in the extending direction and an intersection of a wafer 130 adjacent to a main surface of the corresponding wafer 130 and the first nozzle 201 when the adjacent wafer 130 extends in the extending direction. Also, each of the plurality of gas supply holes 222 is configured to be formed between an intersection of a corresponding wafer 130 and the second nozzle 202 when the corresponding wafer 130 extends in the extending direction and an intersection of a wafer 130 adjacent to a main surface of the corresponding wafer 130 and the second nozzle 202 when the adjacent wafer 130 extends in the extending direction.

Thus, since the hydrogen chloride (HCl) gas, the chlorine (Cl₂) gas, and the chlorine radicals may be supplied in a direction substantially perpendicular to the gap regions between the wafers 130, supply of sufficient amounts of the hydrogen chloride (HCl) gas, the chlorine (Cl₂) gas, and the chlorine radicals to the central parts of the wafers 130 may be guaranteed, and the etching gases may be more efficiently used.

Also, according to the current embodiment, the chlorine (Cl₂) gas and the hydrogen chloride (HCl) gas may be further supplied between the upper and lower ends of the boat 105 during the process without installing a plurality of nozzles, thereby reducing the number of members to be installed in the process chamber 109 and saving the manufacturing costs of the substrate processing apparatus. Also, since each of the chlorine (Cl₂) gas and the hydrogen chloride (HCl) gas may become one system, the gas supply system may be simplified, thereby easily controlling the gas supply system during the substrate processing process.

### Fifth Embodiment of the Present Invention

Next, the fifth embodiment of the present invention will be described. In the current embodiment, a method of etching the wafers 130 when an insulating film and a silicon (Si) film are exposed on each of the wafers 130 will be described. Since silicon substrates are used in the current embodiment, the silicon substrates are configured to include the silicon (Si) film. However, the current embodiment may also be applied to a case in which substrates are each formed of a material other than silicon and an insulating film may be formed to expose the silicon (Si) film.

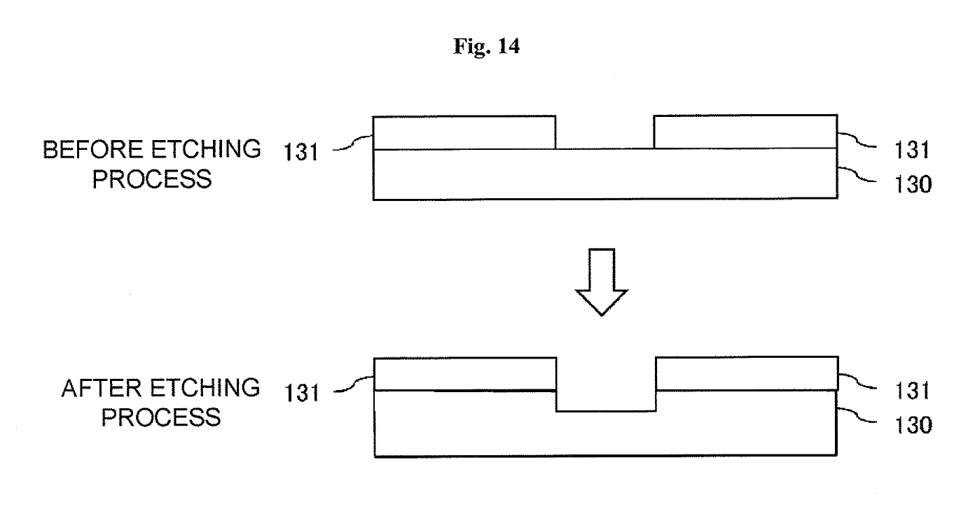

FIG. 14 is a diagram illustrating a process of etching a wafer 130 on which an insulating film is formed, according to the fifth embodiment of the present invention. Referring to FIG. 14, an insulating film 131 formed of, for example, silicon dioxide (SiO₂) and silicon nitride (SiN) is formed on the wafer 130 that has yet to be etched so as to partially expose the wafer 130.

The wafer 130 configured as described above is etched by supplying chlorine (Cl₂) gas and hydrogen chloride (HCl) gas thereto. In this case, the chlorine (Cl₂) gas, the hydrogen chloride (HCl) gas, and chlorine radicals are used to selectively etch the wafer 130. That is, since the rate of etching the exposed wafer 130 is greater that that of the insulating film 131, most of the insulating film 131 is not etched and the exposed portion of the wafer 130 is etched. Thus, after the etching process is performed, the exposed portion of the wafer 130 is etched and the other portions thereof covered with the insulating film 131 are not etched as illustrated in FIG. 14.

According to the current embodiment, even when the wafer 130 including the insulating film 131 is etched, a portion in a surface of the wafer 130 exposed between other wafers 130 may be evenly etched.

### Sixth Embodiment of the Present Invention

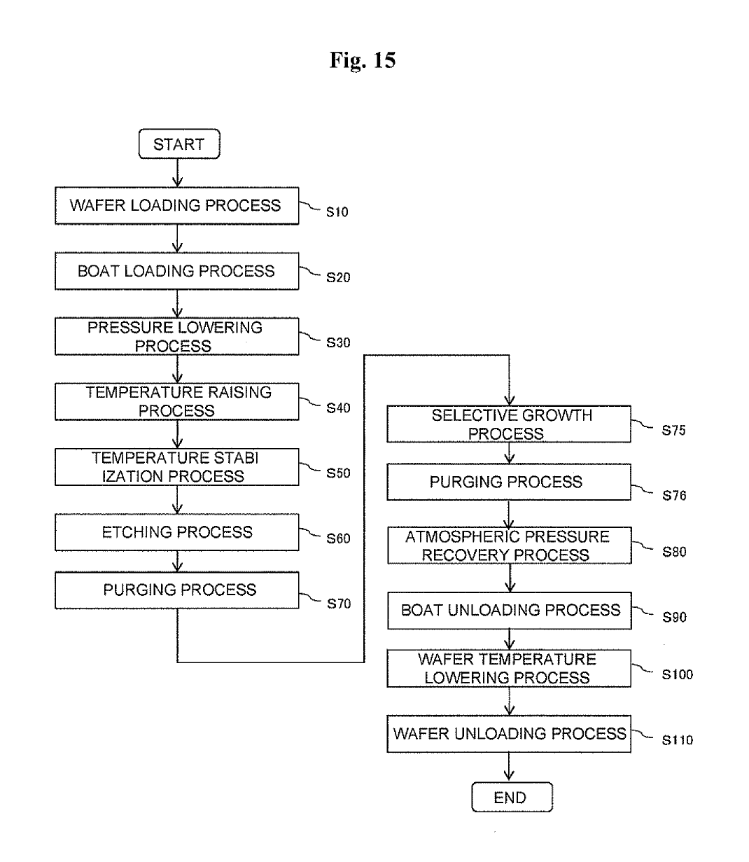

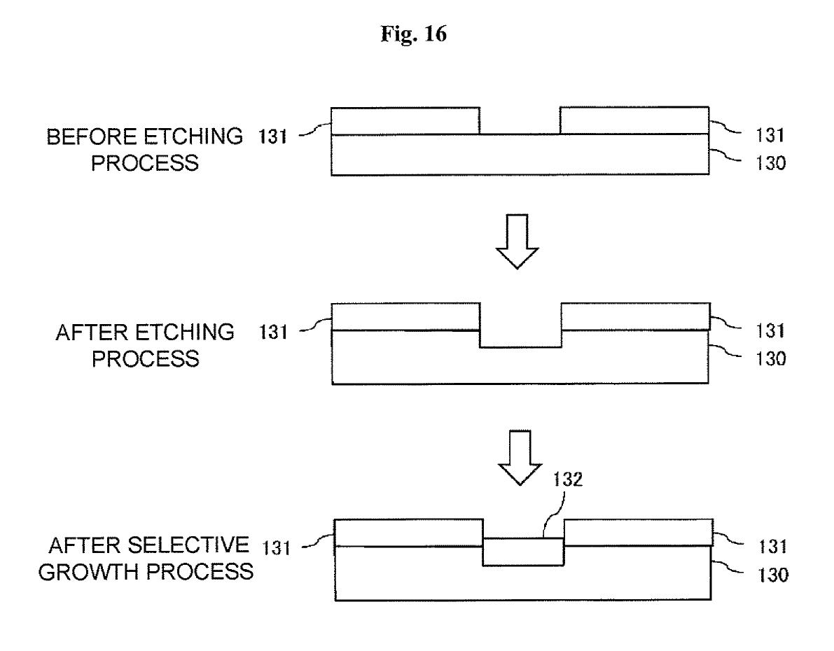

Next, the sixth embodiment of the present invention will be described. In the current embodiment, after the etching process (S60) of FIG. 4 is performed, a process of forming a selective growth film is performed. FIG. 15 is a flowchart illustrating a substrate processing process according to the sixth embodiment of the present invention. FIG. 16 is a diagram illustrating the substrate processing process according to the sixth embodiment of the present invention. In the description below, a case in which the substrate processing apparatus according to the first embodiment is used is described but the present invention is not limited thereto and the substrate processing apparatus according to the second or third embodiment may be used.

The substrate processing process according to the current embodiment includes a wafer loading process (S10), a boat loading process (S20), a pressure lowering process (S30), a temperature raising process (S40), a temperature stabilizing process (S50), an etching process (S60), a purging process (S70), a selective growth process (S75), a purging process (S76), an atmospheric pressure recovery process (S80), a boat unloading process (S90), a wafer temperature lowering process (S100), and a wafer unloading process (S110), as illustrated in FIG. 15. The processes other than the selective growth process (S75) and the purging process (S76) are as described above with respect to the first embodiment and are thus not described in detail again here.

[Selective Growth Process (S75)]

After the inside of the process chamber 109 is purged following etching the wafer 130 [purging process (S70)], a silicon-containing gas and an etching gas are simultaneously supplied into the process chamber 109 to form, for example, a silicon (Si) film or a silicon germanium (SiGe) film on the wafer 130.

First, supply of nitrogen (N₂) gas into the process chamber 109 is suspended by closing the valve 201f of the first carrier gas supply pipe 201d. Then, a silicon-containing gas is supplied as a film-forming gas to the first film-forming gas supply pipe 202g by opening the valve 202i of the first film-forming gas supply pipe 202g. The flow rate of the silicon-containing gas flowing through the first film-forming gas supply pipe 202g is controlled by the MFC 201h. The silicon-containing gas, the flow rate of which is controlled, is supplied to the region between the upper end of the boat 105 and the upper end of the reaction tube 103 via the front end of the second nozzle 202, while being exhausted via the gas exhaust pipe 116. At the same time, hydrogen (H₂) gas is supplied to the second carrier gas supply pipe 202d by opening the valve 202f of the second carrier gas supply pipe 202d. The flow rate of the hydrogen (H₂) gas flowing through the second carrier gas supply pipe 202d is controlled by the MFC 202e. The hydrogen (H₂) gas, the flow rate of which is controlled, is supplied to the region between the upper end of the boat 105 and the upper end of the reaction tube 103, together with the hydrogen chloride (HCl) gas, while being heated by the heater 101. The hydrogen (H₂) gas promotes diffusion of the film-forming gas in the process chamber 109, and is exhausted via the gas exhaust pipe 116. When the silicon germanium (SiGe) film is formed, not only the silicon-containing gas described above but also a germanium-containing gas (film-forming gas), e.g., monogerman (GeH₄) gas, is supplied into the process chamber 109, together with the carrier gas.

Also, chlorine (Cl₂) gas is supplied into the first gas supply pipe by opening the valve 201c of the first gas supply pipe 201a or hydrogen chloride (HCl) gas is supplied into second gas supply pipe 202a by opening the valve 202c of the second gas supply pipe 202a.

In this case, the APC valve 116b is appropriately adjusted to set the pressure in the process chamber 109 to fall within a range of 10 Pa to 100 Pa. The flow rate of the silicon-containing gas is set to fall within, for example, a range of 0 to 1,000 sccm by appropriately adjusting the valve 202i of the first film-forming gas supply pipe 202g. The flow rate of the carrier gas, e.g., the hydrogen (H₂) gas or the nitrogen (N₂) gas, is set to fall within, for example, a range of 0 to 20,000 sccm by appropriately adjusting the valve 201f of the first carrier gas supply pipe 201d or the valve 202f of the second carrier gas supply pipe 202d. The flow rate of the germanium-containing gas is set to fall within, for example, a range of 0 to 1,000 sccm. The flow rates of the chlorine (Cl₂) gas and the hydrogen chloride (HCl) gas (etching gas) are set to fall within, for example, a range of 0 to 500 sccm. An inner temperature of the process chamber 109 is set to fall within, for example, a range of 400° C. to 800° C. by appropriately controlling the heater 101 (including the heaters 101a, 101b, 101c, 101d and 101e).

A selective growth film 132 is selectively formed on the exposed portion of the wafer 130 by simultaneously supplying the film-forming gas and the etching gas into the process chamber 109. This will be described in detail. When the film-forming gas is supplied, a silicon-containing film is formed on the exposed portion of the wafer 130 and the insulating film 131. However, the speed of forming the silicon-containing film on the insulating film 131 is lower than that of forming the silicon-containing film on the exposed portion of the wafer 130, and thus the silicon-containing film is slightly formed on the insulating film 131. Also, since the speed of etching the insulating film 131 is higher than the speed of forming the silicon-containing film on the insulating film 131, the silicon-containing film formed on the insulating film 131 is etched and the silicon-containing film hardly remains on the insulating film 131. On the other hand, the silicon-containing film is formed on the exposed portion of the wafer 130 earlier than on the insulating film 131. Also, since the speed of etching the exposed portion of the wafer 130 is lower than the speed of forming the silicon-containing film on the exposed portion of the wafer 130, the silicon-containing film is formed while being partially etched. As a result, the selective growth film 132 is formed on the exposed portion of the wafer 130.

[Purging Process (S76), Atmospheric Pressure Recovery Process (S80)]

After the selective growth process (S75) is completed, the purging process (S76) is performed.

First, the supply of the film-forming gas, the chlorine (Cl₂) gas, the hydrogen chloride (HCl) gas and the hydrogen (H₂) gas into the process chamber 109 is suspended by closing the valve 202i of the first film-forming gas supply pipe 202g, and then closing the valve 201c of the first gas supply pipe 201a and the valve 201f of the first carrier gas supply pipe 201d when the chlorine (Cl₂) gas is supplied as an etching gas, or closing the valve 202c of the second gas supply pipe 202a and the valve 202f of the second carrier gas supply pipe 202d when the hydrogen chloride (HCl) gas is supplied as an etching gas. Next, an inert gas, e.g., nitrogen (N₂) gas, is supplied to the first carrier gas supply pipe 201d by opening the valve 201f of the first carrier gas supply pipe 201d. The flow rate of the nitrogen (N₂) gas flowing through the first carrier gas supply pipe 201d is controlled by the MFC 201e. The inert gas, the flow rate of which is adjusted, is supplied to the region between the upper end of the boat 105 and the upper end of the reaction tube 103 via the front end of the first nozzle 201 while being exhausted via the gas exhaust pipe 116. After the selective growth operation (S75) is completed by supplying the inert gas into the process chamber 109, the film-forming gas, the etching gases (e.g., the chlorine (Cl₂) gas, the hydrogen chloride (HCl) gas and chlorine radicals), a selective growth reaction material, an etching reaction material, etc. which remain in the process chamber 109 are exhausted via the gas exhaust pipe 116, together with the inert gas.

As described, the inside of the process chamber 109 is purged and the atmosphere in the process chamber 109 is replaced with the inert gas [purging process (S76)]. After the purging of the inside of the process chamber 109 is completed, the inert gas is supplied into the process chamber 109 by appropriately controlling the APC valve 116b of the gas exhaust pipe 116, and the pressure in the process chamber 109 is returned to atmospheric pressure [atmospheric pressure recovery process (S80)].

According to the current embodiment, since the selective growth process (S75) is performed by evenly supplying the etching gases onto each of the wafers 130, the silicon-containing film on the insulating film 131 may be etched, and the selective growth film 132 formed of, for example, a silicon (Si) film or a silicon germanium (SiGe) film, may be certainly formed on only on the exposed portion of each of the wafers 130.

### Other Embodiments of the Present Invention

Although various embodiments of the present invention have been described above, the present invention is not limited thereto and various changes in form and details may be made without departing from the spirit and scope of the invention as defined by the appended claims.

For example, the speed of etching the wafer 130 may be increased by changing a material of a surface of the wafer 130 opposite to a main surface of the wafer 130 to be etched. In detail, if the opposite surface is formed of a material that is more slowly etched than the material of the main surface, then the main surface may be selectively etched when an etching gas arrives at a gap region between the main surface and the opposite surface. Thus, since the amount of the etching gas consumed at the main surface is greater than at the opposite surface, the speed of etching the wafer 130 may be increased. Specifically, when a main surface of a silicon substrate is etched, a silicon dioxide (SiO₂) film may be formed on the surface opposite to the main surface. Since the speed of etching the silicon dioxide (SiO₂) film is lower than that of etching the silicon substrate, the silicon substrate may be selectively etched, thereby increasing the speed of etching the silicon substrate. Otherwise, the speed of etching the main surface may be controlled by forming an insulating film formed of, for example, monocrystalline silicon (Si) or a silicon nitride (SiN) on the opposite surface.

Although, in the first to fourth embodiments, the etching process (S60) has been described above mainly with respect to a case in which the wafers 130 are etched, the present invention is not limited thereto, and this process may also be applied to etching of an insulating film, a metal film, or other various films that may be formed on the wafer 130.

### Exemplary Embodiments of the Present Invention

Exemplary embodiments of the present invention will be further added here.

A method of manufacturing a semiconductor device according to one embodiment of the present invention includes supplying a first etching gas and a second etching gas having a decomposition rate lower than that of the first etching gas from one end of a substrate accommodating region in a process chamber where a plurality of substrates are stacked while exhausting an inside of a process chamber from other end of the substrate accommodating region; and etching a first portion of the plurality of substrate at the one end of the substrate accommodating region using a portion of radicals generated from the first etching gas and second etching gas, and etching a second portion of the plurality of substrates at the other end of the substrate accommodating region using at least a portion of a remaining radicals of the radicals generated from the first etching gas and second etching gas.

The first etching gas may include a chlorine (Cl₂) gas, and the second etching gas may include a hydrogen chloride (HCl) gas.

A method of manufacturing a semiconductor device according to another embodiment of the present invention includes loading a plurality of stacked substrates into a substrate accommodating region in a process chamber; supplying a chlorine gas and a hydrogen chloride gas form one end of the substrate accommodating region, and exhausting an inside of the process chamber from other end of the substrate accommodating region while etching the plurality of stacked substrates using a portion of chlorine radicals generated from the chlorine gas and the hydrogen chloride gas; and unloading the plurality of stacked substrates from the process chamber.

A method of manufacturing a semiconductor device according to still another embodiment of the present invention includes supplying a chlorine gas and a hydrogen chloride gas from one end of a substrate accommodating region in a process chamber where a plurality of substrates are stacked while exhausting an inside of a process chamber from other end of the substrate accommodating region; and etching a first portion of the plurality of substrates at the one end of the substrate accommodating region using a portion of chlorine radicals generated from the chlorine gas and the hydrogen chloride gas, and etching a second portion of the plurality of substrates at the other end of the substrate accommodating region using at least a portion of a remaining radicals of the radicals generated from the chlorine gas and the hydrogen chloride gas.

A method of manufacturing a semiconductor device according to still another embodiment of the present invention includes supplying a first etching gas and a second etching gas having a decomposition rate lower than that of the first etching gas from one end of a substrate accommodating region in a process chamber where a plurality of substrates are stacked while exhausting an inside of the process chamber from other end of the substrate accommodating region; and etching the plurality of substrates by further supplying at least one of the first etching gas and the second etching gas from a location between the one end and the other end of the substrate accommodating region.

A method of manufacturing a semiconductor device according to still another embodiment of the present invention includes, supplying a chlorine gas and a hydrogen chloride gas from one end of a substrate accommodating region in a process chamber where a plurality of substrates are stacked while exhausting an inside of the process chamber from other end of the substrate accommodating region; and etching the plurality of substrate by further supplying at least one of the chlorine gas and the hydrogen chloride gas from a location between the one end and the other end of the substrate accommodating region.

Preferably, an amount of the chlorine gas supplied from the one end is greater than that of the chlorine gas supplied from the location when the plurality of substrates are etched by supplying the chlorine gas from the location, and an amount of the hydrogen chloride gas supplied from the one end is greater than that of the hydrogen chloride gas supplied from the location when the plurality of substrates are etched by supplying the hydrogen chloride gas from the location.

A method of manufacturing a semiconductor device according to still another embodiment of the present invention includes supplying a chlorine gas and a hydrogen chloride gas from one end of a substrate accommodating region in a process chamber where a plurality of substrates are stacked while exhausting an inside of the process chamber from other end of the substrate accommodating region; and etching the plurality of substrate by further supplying at least the hydrogen chloride gas from a location between the one end and the other end of the substrate accommodating region.

Preferably, an amount of the hydrogen chloride gas supplied from the one end is greater than that of the hydrogen chloride gas supplied from the location when the plurality of substrates are etched by supplying the hydrogen chloride gas from the location.

Preferably, the hydrogen chloride gas and the chlorine gas are supplied from the location.

Preferably, an amount of the chlorine gas supplied from the one end is greater than that of the chlorine gas supplied from the location when the plurality of substrates are etched by supplying the chlorine gas from the location.

A method of manufacturing a semiconductor device according to still another embodiment of the present invention includes supplying a chlorine gas and a hydrogen chloride gas from one end of a substrate accommodating region in a process chamber where a plurality of substrates are stacked while exhausting an inside of the process chamber from other end of the substrate accommodating region; and etching the plurality of substrate by further supplying at least the chlorine gas from a location between the one end and the other end of the substrate accommodating region.

Preferably, when the plurality of substrates are etched, an amount of the chlorine gas supplied from the one end is greater than that of the chlorine gas supplied from a location between the one end and the other end of the substrate accommodating region.

Preferably, when the plurality of substrates are etched, the chlorine gas and the hydrogen chloride gas are thermally decomposed by constantly maintaining an inner temperature of the process chamber within a range between room temperature and 700° C.

Preferably, when the plurality of substrates are etched, a plurality of locations between the one end and the other end of the substrate accommodating region are disposed along a stacking direction of the plurality of substrates, and an amount of the hydrogen chloride gas supplied from the predetermined locations decreases toward the other end of the substrate accommodating region.

Preferably, when the plurality of substrates are etched, a plurality of the predetermined locations between the one end and the other end of the substrate accommodating region are disposed along a stacking direction of the plurality of substrates, and substantially the same amount of the chlorine is supplied from the plurality of the predetermined locations.

A substrate processing apparatus according to one embodiment of the present invention includes a process chamber having a substrate accommodating region where a plurality of substrates are stacked; a gas supply unit configured to supply a first etching gas and a second etching gas having a decomposition rate lower than that of the first etching gas from one end of the substrate accommodating region; and an exhaust unit configured to exhaust an inside of the process chamber from other end of the substrate accommodating region, wherein a first portion of the plurality of substrate at the one end of the substrate accommodating region is etched using a portion of radicals generated from the first etching gas and second etching gas, and etching a second portion of the plurality of substrates at the other end of the substrate accommodating region using at least a portion of a remaining radicals of the radicals generated from the first etching gas and second etching gas.

Preferably, the first etching gas includes a chlorine gas, and the second etching gas includes a hydrogen chloride gas.

A substrate processing apparatus according to another embodiment of the present invention includes a process chamber having a substrate accommodating region where a plurality of substrates are stacked; a gas supply unit configured to supply a chlorine gas and a hydrogen chloride gas from one end of the substrate accommodating region; an exhaust unit configured to exhaust an inside of the process chamber from other end of the substrate accommodating region; and a control unit configured to control the gas supply unit and the exhaust unit, wherein the control unit controls the gas supply unit and the exhaust unit so as to etch a first portion of the plurality of substrate at the one end of the substrate accommodating region using a portion of chlorine radicals generated from the chlorine gas and the hydrogen chloride gas and a second portion of the plurality of substrates at the other end of the substrate accommodating region using at least a portion of a remaining radicals of the chlorine radicals while exhausting the inside of the process chamber from other end of the substrate accommodating region.

A substrate processing apparatus according to still another embodiment of the present invention includes a process chamber having a substrate accommodating region where a plurality of substrates are stacked; a first gas supply unit configured to supply a chlorine gas and a hydrogen chloride gas from one end of the substrate accommodating region; a second gas supply unit configured to supply at least one of the chlorine gas and the hydrogen chloride gas from a location between the one end and other end of the substrate accommodating region opposite to the first end; an exhaust unit configured to exhaust an inside of the process chamber from the other end of the substrate accommodating region; and a control unit configured to control the first gas supply unit, the second gas supply unit and the exhaust unit, wherein the control unit controls the first gas supply unit, the second gas supply unit and the exhaust unit so as to supply the chlorine gas and the hydrogen chloride gas from the one end by the first gas supply unit while exhausting the inside of the process chamber from the other end and etch the plurality of substrate by further supplying at least one of the chlorine gas and the hydrogen chloride gas from the location by the second gas supply unit.

The present invention can provide a method of manufacturing a semiconductor device capable of improving etching uniformity and a substrate processing apparatus.

What is claimed is:

1. A method of manufacturing a semiconductor device, comprising:
supplying a first etching gas and a second etching gas having a decomposition rate lower than that of the first etching gas from one end of a substrate accommodating region in a process chamber where a plurality of substrates are stacked while exhausting an inside of a process chamber from other end of the substrate accommodating region; and
etching a first portion of the plurality of substrate at the one end of the substrate accommodating region using a portion of radicals generated from the first etching gas and second etching gas, and etching a second portion of the plurality of substrates at the other end of the substrate accommodating region using at least a portion of a remaining radicals of the radicals generated from the first etching gas and second etching gas.

2. The method of claim 1, wherein the first etching gas comprises a chlorine gas, and the second etching gas comprises a hydrogen chloride gas.

3. The method of claim 2, wherein, when the plurality of substrates are etched, an amount of the chlorine gas supplied from the one end of the substrate accommodating region is greater than that of the chlorine gas supplied from a location between the one end and the other end of the substrate accommodating region.

4. The method of claim 2, wherein, when the plurality of substrates are etched, the chlorine gas and the hydrogen chloride gas are thermally decomposed by constantly maintaining an inner temperature of the process chamber within a range between room temperature and 700° C.

5. The method of claim 2, wherein, when the plurality of substrates are etched, a plurality of locations between the one end and the other end of the substrate accommodating region are disposed along a stacking direction of the plurality of substrates, and an amount of the hydrogen chloride gas supplied from the predetermined locations decreases toward the other end of the substrate accommodating region.

6. The method of claim 2, wherein, when the plurality of substrates are etched, a plurality of the predetermined locations between the one end and the other end of the substrate accommodating region are disposed along a stacking direction of the plurality of substrates, and substantially same amount of the chlorine is supplied from each of the plurality of the predetermined locations.

7. A method of manufacturing a semiconductor device, comprising:
supplying a chlorine gas and a hydrogen chloride gas from one end of a substrate accommodating region in a process chamber where a plurality of substrates are stacked while exhausting an inside of the process chamber from other end of the substrate accommodating region; and
etching the plurality of substrate by further supplying at least one of the chlorine gas and the hydrogen chloride gas from a location between the one end and the other end of the substrate accommodating region.

8. The method of claim 7, wherein an amount of the chlorine gas supplied from the one end is greater than that of the chlorine gas supplied from the location when the plurality of substrates are etched by supplying the chlorine gas from the location, and
an amount of the hydrogen chloride gas supplied from the one end is greater than that of the hydrogen chloride gas supplied from the location when the plurality of substrates are etched by supplying the hydrogen chloride gas from the location.

9. A substrate processing apparatus comprising:
a process chamber having a substrate accommodating region where a plurality of substrates are stacked;
a gas supply unit configured to supply a first etching gas and a second etching gas having a decomposition rate lower than that of the first etching gas from one end of the substrate accommodating region; and
an exhaust unit configured to exhaust an inside of the process chamber from other end of the substrate accommodating region,
wherein a first portion of the plurality of substrate at the one end of the substrate accommodating region is etched using a portion of radicals generated from the first etching gas and second etching gas, and
etching a second portion of the plurality of substrates at the other end of the substrate accommodating region using at least a portion of a remaining radicals of the radicals generated from the first etching gas and second etching gas.

10. The substrate processing apparatus of claim 9, wherein the first etching gas comprises a chlorine gas, and the second etching gas comprises a hydrogen chloride gas.

11. A substrate processing apparatus comprising:
a process chamber having a substrate accommodating region where a plurality of substrates are stacked;
a gas supply unit configured to supply a chlorine gas and a hydrogen chloride gas from one end of the substrate accommodating region;
an exhaust unit configured to exhaust an inside of the process chamber from other end of the substrate accommodating region; and
a control unit configured to control the gas supply unit and the exhaust unit,
wherein the control unit controls the gas supply unit and the exhaust unit so as to etch a first portion of the plurality of substrate at the one end of the substrate accommodating region using a portion of chlorine radicals generated from the chlorine gas and the hydrogen chloride gas and a second portion of the plurality of substrates at the other end of the substrate accommodating region using at least a portion of a remaining radicals of the chlorine radicals while exhausting the inside of the process chamber from a second end of the substrate accommodating region.
